(19) United States
(12) Patent Application Publication
(10) Pub. No.: US 2011/0291208 A1
(43) Pub. Date: Dec. 1, 2011

(54) ELEMENT STRUCTURE, INERTIA SENSOR, AND ELECTRONIC DEVICE

(75) Inventor: Shigekazu TAKAGI, Shimosuwa (JP)

(73) Assignee: SEIKO EPSON CORPORATION, Tokyo (JP)

(21) Appl. No.: 13/115,632

(22) Filed: May 25, 2011

(30) Foreign Application Priority Data
May 27, 2010 (JP) 2010-121727

(51) Int. Cl. H01L 29/84

(52) U.S. Cl. 257/417; 257/E29.324

(57) ABSTRACT

Manufacturing of an element structure including a capacitor is to be facilitated. An element structure includes a first substrate that has a first support layer and a first movable beam having one end supported side the first support layer and the other end having a void part provided therearound and a second substrate that has a second support layer and a first fixing electrode formed side the second support layer wherein the second substrate is disposed to face above the first substrate, the first movable beam is provided with a first movable electrode and the first fixing electrode and the first movable electrode are disposed to face each other, with a gap therebetween.

### BACKGROUND

1. Technical Field

The present invention relates to an element structure, an inertia sensor, and an electronic device.

2. Related Art

Recently, there has been interest in a technology capable of implementing a small-sized and highly sensitive micro-electromechanical system (MEMS) sensor using a MEMS technology. For example, JP-A-2004-286535 discloses a structure of a capacitive MEMS acceleration sensor.

In a technology disclosed in JP-A-2004-286535, a movable beam structure, a movable electrode integrally operated with the beam structure, a spring part supporting the beam structure, a first fixing electrode, and a second fixing electrode are formed by depositing polysilicon on a support substrate and processing the polysilicon or the like, by photolithography. By this configuration, a capacitor having a structure (insulating structure) in which an insulating layer is provided between the movable electrode and the fixing electrode is formed. By the sensor structure, an acceleration component in a direction (Z-axis) perpendicular to a substrate may be detected as a change in capacitance.

In the technology disclosed in JP-A-2004-286535, it is necessary to provide three insulating separating structures in a direction perpendicular to a substrate within a structure. As a result, the manufacturing process becomes complicated.

Further, there are limitations on improving the sensitivity of a sensor or reducing a sensor size due to the complexity of the structure. That is, since the electrode (polysilicon) is formed by a deposition process and it is difficult to thicken a layer in terms of the process, there is a limitation on improving the sensor performance.

Further, when performing a sealing (packaging) of the sensor element, an additional process is required and the manufacturing process becomes more complicated.

### SUMMARY

An advantage of some aspects of the invention is to, for example, facilitate the manufacturing of an element structure including a capacitor.

(1) An element structure according to an aspect of the invention includes a first substrate that has a first support layer and a first movable beam having one end supported and the other end having a void part provided therearound; and a second substrate that has a second support layer and a first fixing electrode formed side the first support layer, wherein the second substrate is disposed to face above the first substrate, the first movable beam is provided with a first movable electrode and the first fixing electrode and the first movable electrode are disposed to face each other, with a gap therebetween.

According to this aspect of the invention, capacitance in a direction (for example, Z-axis direction) perpendicular to each substrate may be detected by at least two substrates, i.e., the first substrate and second substrate and the structure of a capacitor may be simplified.

(2) In another aspect of the invention, an insulating layer is provided at least one between the first support layer and the first movable beam and between the second support layer and the first fixing electrode.

According to this aspect of the invention, the insulation of the first substrate or the second substrate is secured by the insulating layer. Accordingly, it is not necessary to form a special structure for isolating between conductor layers disposed on each substrate. That is, when the first substrate and the second substrate face each other at a predetermined distance, the isolation between the conductor layers (conductive members) is essentially realized in the direction (for example, Z-axis direction) perpendicular to each substrate. As a result, the manufacturing process of the element structure including the capacitor is simplified.

Further, when, for example, an SOI substrate having a thick active layer is used and the movable beam is configured using the thick active layer, a mass (mass of a movable weight) necessary to detect an inertia force (physical quantity such as acceleration or angular velocity) with high accuracy may be easily secured. Therefore, the sensor sensitivity is easily improved.

(3) In another aspect of the invention, the element structure may be configured such that the first substrate is further provided with a second fixing electrode, the second substrate is further provided with a second movable beam having one end supported side the first support layer and the other end having a void part provided therearound, the second movable beam is provided with a second movable electrode, and the second fixing electrode and the second movable electrode are disposed to face each other, with a gap therebetween.

According to this aspect of the invention, the element structure including two capacitors (first capacitor and second capacitor) may be obtained. For the first capacitor, the first movable electrode is disposed on the first substrate side and the first fixing electrode is disposed on the second substrate side. On the other hand, for the second capacitor, the second movable electrode is disposed on the second substrate side and the second fixing electrode is disposed on the first substrate side. That is, in the first capacitor and the second capacitor, the positional relationship between the movable electrode and the fixing electrode is in a reverse state. Therefore, the first capacitor and the second capacitor may be used as differential capacitors.

When a force (acceleration or Coriolis force) is applied in a direction (for example, Z-axis direction) perpendicular to each substrate, for example, in the first capacitor, the capacitance value of the first capacitor is reduced by increasing the distance (gap between capacitors) between the first movable electrode and the first fixing electrode (variation of the capacitance value of the first capacitor is set to be “−ΔC”). In this case, in the second capacitor, the capacitance value of the second capacitor is increased by reducing the distance (gap between the capacitors) between the second movable electrode and the second fixing electrode (variation of the capacitance value of the second capacitor is set to be “+ΔC”).

The differential detection signal is obtained by converting the variation in the capacitance values of each of the first capacitor and the second capacitor into the electrical signal. In-phase noise may be offset by differentiating the detection signal. Further, a direction of force (direction in which force is applied) may also be detected by detecting which one of two detection signals is increased. Further, since the capacitance value of the capacitor for detecting the inertia force is substantially increased and the movement of charge is increased by disposing the plurality of capacitors (that is, first capacitor and second capacitor), the signal amplitude of the detection signal may be increased.

Further, when the structure according to this aspect of the invention is used, crosstalk (interaction) due to a coupling between the first capacitor and the second capacitor may be practically reduced to a level that does not cause any problem. For example, the case in which the fixing electrode of the capacitor is used as a common potential and the detection signal is obtained from the movable electrode is considered. Generally, as the element structure is miniaturized, the distance between the first capacitor and the second capacitor is shortened, and the coupling due to parasitic capacitance may easily occur between the movable capacitances of each capacitor.

However, according to the structure of the element structure of this aspect of the invention, as described above, the first movable electrode of the first capacitor is disposed on the first substrate side, while the second movable electrode of the second capacitor is disposed on the second substrate side. Since each substrate is spaced by the predetermined distance in a direction (for example, Z-axis direction) perpendicular to the substrate, even though the first variable capacitor and the second variable capacitor are disposed to be adjacent to each other, the distance between the first movable electrode and the second movable electrode is secured, such that the crosstalk (interaction) due to the coupling between the first capacitor and the second capacitor is sufficiently reduced. Accordingly, according to this aspect of the invention, the reduction in the detection sensitivity may be suppressed while miniaturizing the element structure.

(4) In another aspect of the invention, the element structure may be configured such that the first substrate is partitioned into first to fourth areas by a first axis passing through a center of the first substrate and a second axis orthogonal to the first axis at the center, when seen in plan view, at least a portion of the first area and the second area disposed in a point symmetry with respect to the center is provided with a forming area of the first movable electrode, at least a portion of the third area and the fourth area disposed in a point symmetry with respect to the center is provided with a forming area of the second fixing electrode, the second substrate is partitioned into a fifth area facing the first area, a sixth area facing the second area, a seventh area facing the third area, and an eighth area facing the fourth area, when seen in plan view, at least a portion of the fifth area and the sixth area is provided with a forming area of the first fixing electrode, and at least a portion of the seventh area and the eighth area is provided with a forming area of the second movable electrode.

In this aspect of the invention, for the electrode forming areas, the point symmetrical arrangement (when rotating 180° based on a symmetrical point, there is an arrangement so as to overlap an original diagram (diagram showing an original area)) is adopted and the line symmetrical arrangement (when folding based on the symmetrical axis, there is an arrangement so as to overlap an original diagram (diagram showing an original area)) is adopted. As a result, for example, the electrode arrangement layout of each of the first substrate and the second substrate may be made common. Therefore, the substrate is efficiently manufactured.

For example, after two sheets of substrates adopting the common electrode arrangement layout are prepared and each substrate is processed by using a common mask, each substrate faces the other to be connected face-to-face. As a result, the forming area of the first movable beam (first movable electrode) on the first substrate and the forming area of the first fixing part (first fixing electrode) on the second substrate are in an opposing state, such that the first capacitor is formed and similarly, the forming area of the second movable beam (second movable electrode) on the second substrate and the forming area of the second fixing part (second fixing electrode) on the first substrate are in an opposing state, such that the second capacitor is formed.

When the electrode arrangement layout according to this aspect of the invention is not adopted, the electrode arrangement layout for the first substrate and the electrode arrangement layout for the second substrate need to be in a horizontally (or vertically) inverted layout, when seen in plan view (otherwise, when each substrate is bonded to the other face-to-face, the first capacitor and the second capacitor may not be formed), such that the electrode arrangement layout needs to be changed corresponding to each substrate, thereby degrading the manufacturing efficiency of the substrates.

(5) In another aspect of the invention, the element structure may be configured such that the first movable electrode is formed in the first area and the second area, the first fixing electrode is formed in the fifth area and the sixth area, the second movable electrode is formed in the seventh area and the eighth area, and the second fixing electrode is formed in the third area and the fourth area.

According to this aspect of the invention, in each substrate, even in the electrode arrangement and the electrode shape, the point symmetry is secured. According to this aspect of the invention, the capacitance values of the capacitors (first capacitor and second capacitor) may be determined with higher accuracy.

For example, the substrate adopting the common electrode arrangement layout is manufactured in two parts and each substrate faces the other to be connected face-to-face. At the time of manufacturing any one substrate, when the mask misalignment occurs in a predetermined direction, even at the time of manufacturing the other substrate, the mask misalignment occurs in the predetermined direction (the reason is that the common mask is used). Further, when the point symmetry and the line symmetry are secured even in the shape of the electrodes in each substrate, the first substrate and the second substrate are bonded to each other face-to-face, and the opposite area between the respective electrodes is accurately determined as the area of the electrode itself, regardless of whether the mask misalignment occurs. Therefore, according to this aspect of the invention, the capacitance values of the capacitors (first capacitor and second capacitor) may be determined with higher accuracy.

Since the first capacitor and the second capacitor configure the differential capacitors, it is preferable that the change in the capacitance values occurring in each capacitor is different only in a sign and is the same in the absolute value. According to this aspect of the invention, each area of the first capacitor and the second capacitor may be accurately determined by the electrode shape itself, such that the differential detection output may be obtained with high accuracy.

(6) In another aspect of the invention, the element structure may be configured such that a spacer member is disposed between the first substrate and the second substrate.

For example, the second substrate can be held on the first substrate, while being spaced by the predetermined distance, by the spacer member. As the spacer member, an insulating spacer member configured of only an insulating material may be used and a conductive spacer member including conductive materials as a component may be used. Further, both of the insulating spacer member and the conductive spacer member may be used.

(7) In another aspect of the invention, the element structure may be configured such that the spacer member is a frame shape and a sealing body is formed to have a space therein by the first substrate, the second substrate, and the space member.

For example, the first substrate may be used as a support substrate that supports the second substrate, the second substrate may be used as a lid substrate configuring a lid part of the sealing body, and the spacer member may be used as a side wall for airtight sealing. After the spacer member having a closed linear shape when seen in plan view is formed on at least one of the first substrate and the second substrate, the element structure including the sealing body (package) is formed by bonding the first substrate and the second substrate face-to-face. According to this aspect of the invention, an additional manufacturing process for configuring the sealing body (package) is not required, such that the manufacturing process of the element structure is simplified.

(8) In another aspect of the invention, the element structure may be configured such that the spacer member is a column shape and is disposed around the center of the area in which the first substrate and the second substrate overlap each other.

The central portion of the second substrate as the lid substrate is a portion that is easily bent. Therefore, supporting the second substrate by the spacer member efficiently suppresses the bending of the second substrate.

(9) In another aspect of the invention, the element structure may be configured such that the spacer member includes a resin core part and a conductive layer formed to cover at least a portion of a surface of the resin core part.

According to this aspect of the invention, the conductive spacer member (spacer including the conductive material as a component) having the resin core structure including the resin core part (resin core) as the spacer member and the conductive layer formed to cover at least a portion of the surface of the resin core part (resin core) is used.

As the resin, for example, a thermosetting resin such as resin may be used. The resin is hardened and has rigidity, which serves to stably support (support at the predetermined distance) the second substrate on the first substrate. Further, the conductor layer is formed to cover (to contact at least the resin core) at least a portion of the surface of the resin core part.

Further, the thickness of the conductor layer is thin (further, when the first substrate is bonded to the second substrate, there may be a case in which an apex portion of the resin core is almost exposed) such that the distance between the first substrate and the second substrate may be accurately determined as the height of the resin core.

Further, since the conductor layer covering at least a portion of the resin core is provided, for example, the conductor on the first substrate side and the conductor on the second substrate side may also be connected with each other via the conductor layer. Further, when, for example, the conductive spacer having the resin core structure is interposed between the insulating layer of the first substrate side and the insulating layer of the second substrate, it does not exhibit a function to electrically conduct with the conductor layer covering at least a portion of the resin core. In this case, the conductive spacer having the resin core structure may substantially serve as the insulating spacer.

(10) An inertia sensor according to one aspect of the invention includes the element structure according to any one of the above descriptions and a signal processing circuit that processes electrical signals output from the element structure.

The element structure is compact and has the high detection performance. Therefore, the small-sized and highly sensitive inertia sensor may be implemented. Further, the inertia sensor having the sealing body (package) and high reliability (that is, excellent moisture resistance, or the like) may be obtained. An example of the inertia sensor may include a capacitive acceleration sensor and a capacitive gyro sensor (angular velocity sensor).

(11) An electronic device according to one aspect of the invention has the above-mentioned element structure.

As a result, small-sized and high-performance (high reliability) electronic devices (for example, game controllers, portable terminals, or the like) may be obtained.

### BRIEF DESCRIPTION OF THE DRAWINGS

The invention will be described with reference to the accompanying drawings, wherein like numbers reference like elements.

FIGS. 1A to 1C are diagrams showing a structure example of an element structure including a capacitor.

FIGS. 2A to 2C are diagrams showing an example of an element structure including a first capacitor and a second capacitor and an example of an inertia sensor using the element structure.

FIG. 3 is a diagram showing a configuration example of the inertia sensor.

FIGS. 4A to 4C are diagrams for illustrating a configuration and an operation of a C/V conversion circuit.

FIGS. 5A and 5B are diagrams showing a detailed example of a structure of an SOI substrate and a detailed example of a structure of the element structure using the SOI substrate.

FIGS. 6A and 6B are diagrams showing an exemplary example of an electrode arrangement and an electrode shape in one SOI substrate configuring the element structure.

FIG. 7 is a diagram showing an arrangement example of a connection terminal in the element structure.

FIG. 8 is a diagram showing an example in which a first substrate is bonded to a second substrate.

FIGS. 9A and 9B are cross-sectional views taken along line A-A′ and line B-B′ of the element structure after chips are bonded as shown in FIG. 8.

FIG. 10 is a cross-sectional view taken along line C-C′ of the element structure after the chips are bonded as shown in FIG. 8.

FIGS. 11A and 11B are diagrams showing an example of an arrangement of an exemplary spacer member.

FIG. 12 is a diagram showing an example of a structure of a wiring.

FIG. 13 is a diagram showing another example of the structure of the wiring.

FIGS. 14A and 14B are diagrams showing a detailed structure example of the element structure.

FIGS. 15A and 15B are enlarged views of a sectional structure around the spacer having a resin core structure in a state in which the first substrate is bonded to the second substrate.

FIGS. 16A and 16B are cross-sectional views of the element structure corresponding to a first process in a manufacturing method of an element structure (having the structure shown in FIG. 14B).

FIGS. 17A and 17B are cross-sectional views of the element structure in a second process.

FIGS. 18A to 18C are cross-sectional views of the element structure in a third process.

FIGS. 19A to 19C are cross-sectional views of the element structure in a fourth process.

FIGS. 20A and 20B are cross-sectional views of the element structure in a fifth process.

FIG. 21 is a diagram showing an example of a configuration of an electronic device.

FIG. 22 shows another example of a configuration of an electronic device.

### DESCRIPTION OF EXEMPLARY EMBODIMENTS

Hereinafter, exemplary embodiments of the invention will be described with reference to the accompanying drawings. The embodiments of the invention to be described below are not excessively limited only to the contents of the appended claims, and the entire configurations disclosed in the embodiments are not necessarily essential as a solving means according to the invention.

### First Embodiment

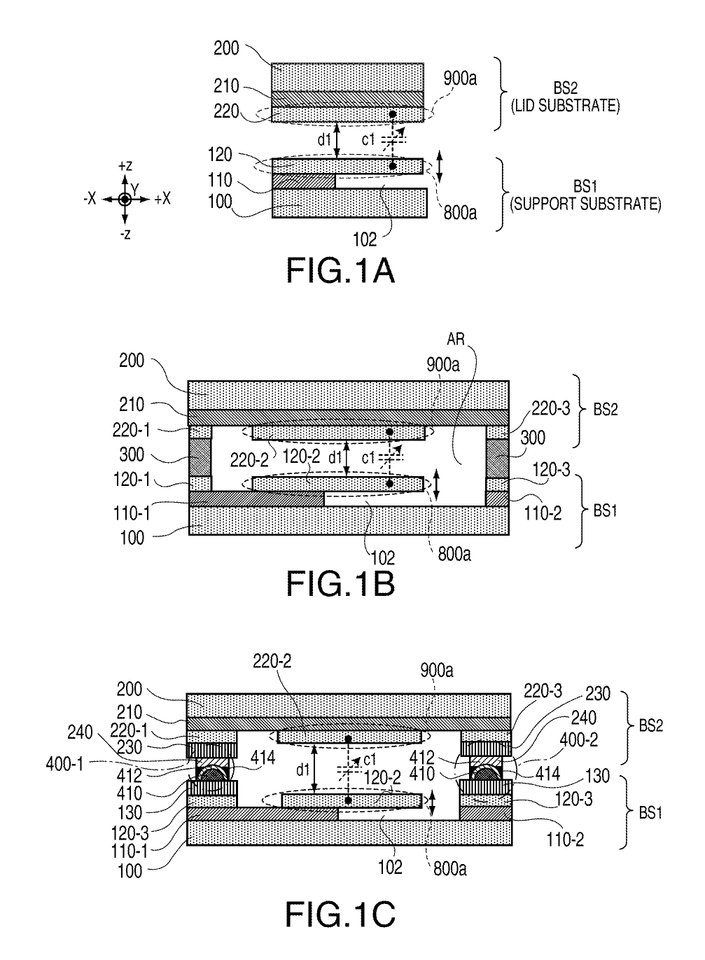

FIGS. 1A to 1C show a structure example of an element structure including a capacitor. In an example of FIG. 1A, an element structure is configured to include a first substrate BS1 and a second substrate BS2 that are disposed to face each other, while being spaced by a predetermined distance d1. As the first substrate BS1 and the second BS2, for example, an SOI substrate may be used (however, a glass substrate, or the like, may be used as an insulating substrate, without being limited thereto).

The first substrate BS1 includes a first support layer (for example, a silicon single crystal layer) 100, a first insulating layer (for example, a silicon oxide layer) 110 formed on the first support layer 100, and a first movable beam 800a having one end supported on the first insulating layer 110 and the other end having a void part 102 provided therearound. The first movable beam 800a is formed by patterning a first active layer (for example, a silicon single crystal layer) 120 formed on the insulating layer 110.

Further, the second substrate BS2 includes a second support layer (for example, a silicon single crystal layer) 200, a second insulating layer (for example, a silicon oxide layer) 210 formed on the second support layer 200, and a first fixing part 900a fixed on the second insulating layer 210. The first fixing part 900a is formed by patterning a second active layer (for example, a silicon single crystal layer) 220 formed on the insulating layer 210.

The first movable beam 800a and the first fixing part 900a are disposed to face each other, while being spaced by the predetermined distance d1, and a first capacitor c1 is provided between the first movable beam 800a as a first movable electrode and the first fixing part 900a as a first fixing electrode.

The element structure shown in FIG. 1A may be used as a component of a capacitive MEMS acceleration sensor or an inertia sensor such as a capacitive MEMS gyro sensor, or the like. For example, when a displacement in a direction perpendicular to a substrate (Z-axis direction) is generated in the movable beam 800a by, for example, acceleration, a capacitance value of the first capacitor c1 is changed. The acceleration may be detected by converting the change in the capacitance value into an electrical signal by a C/V conversion circuit (capacitance/voltage conversion circuit). Similarly, when the displacement in the direction (Z-axis direction) perpendicular to the substrate is generated in the movable beam 800a by a Coriolis force due to rotation, a capacitance value of the first capacitor c1 is changed. An angular velocity may be detected by converting the change in the capacitance value into an electrical signal by the C/V conversion circuit (capacitance/voltage conversion circuit: not shown in FIGS. 1A to 1C). Further, in the gyro sensor, the element structure is attached to, for example, a rotating body (rotating mass body: not shown) that rotates at a predetermined rotational frequency.

In an example of FIG. 1B, an SOI substrate is used as the first substrate BS1 and the second substrate BS2. A spacer member 300 (herein, referred to as an insulating spacer member) is disposed between the first substrate BS1 and the second substrate BS2. As the spacer member 300, for example, a resist layer or a resin layer such as resin may be used. In the example of FIG. 1B, for example, the second substrate BS2 is maintained on the first substrate BS1, while being spaced by the predetermined distance d1, by the spacer member 300.

In the first substrate BS1 shown in the example of FIG. 1B, the first insulating layer 110 on the first support layer 100 is patterned such that the patterned first insulating layers 110-1 and 110-2 remain. On the other hand, a portion in which the first insulating layer 110 is removed is provided with a first cavity part 102. Further, the first active layer 120 on the first insulating layer 110 is patterned such that the patterned first active layers 120-1, 120-2, and 120-3 remain. The patterned first active layer 120-2 becomes the first movable beam 800a. One end of the first movable beam 800a is supported by the first insulating layer 110 and the surroundings of the other end of the first movable beam 800a are provided with the first void part 102.

Further, in the second substrate BS2 shown in FIG. 1B, the second active layer 220 is patterned such that the patterned second active layers 220-1, 220-2, and 220-3 remain. The patterned second active layer 220-2 serves as the first fixing part 900a.

In the element structure shown in the examples shown in FIGS. 1A and 1B, each of the first substrate BS1 and the second substrate BS2 is disposed in the state in which they face each other, while being spaced by the predetermined distance d1 and thus, the insulation between the first substrate BS1 and the second substrate BS2 is secured. Accordingly, in order to isolate between conductor layers (active layers 120 and 220, or the like) disposed on each substrate BS1 and BS2, it is not necessary to form a special structure.

That is, when the first substrate BS1 and the second substrate BS2 face each other, while being spaced by the predetermined distance d1, the isolation between the conductor layers (conductive members) is essentially realized in the direction perpendicular to each substrate BS1 and BS2 (for example, Z-axis direction). As a result, the manufacturing process of the element structure including the capacitor is simplified.

Further, when for example, as the first substrate BS, the SOI substrate of which the thickness of the first active layer 120 is increased is used and the first movable beam 800a is configured using the thick first active layer 120, a mass (a mass of a movable weight: a movable mass) necessary to detect an inertia force (physical quantity such as acceleration or angular velocity) with high accuracy may be easily secured. Therefore, the sensor sensitivity is easily improved.

Further, when for example, the SOI substrate of which the thickness of the active layer is increased is used and the first movable beam 800a is configured using the thick first active layer 120, a mass (mass of a movable weight: a movable mass) necessary to detect an inertia force (physical quantity such as acceleration or angular velocity) with high accuracy may be easily secured. Since the mass per unit area is large, a small-sized sensor may be easily designed while securing the sensor sensitivity.

Further, in the example of FIG. 1B, a sealing body is easily formed. That is, in the example of FIG. 1B, the first substrate BS1 may be used as “a support substrate” that supports the second substrate BS2, the second substrate BS2 may be used as “a lid substrate” forming a lid part of the sealing body, and the spacer member 300 may be used as, for example, “a side wall (sealing member) for airtight sealing”.

For example, after the spacer member 300 having a closed linear shape when seen in plan view is formed on at least one of the first substrate BS1 and the second substrate BS2, the element structure including the sealing body (airtight sealing package) having a space AR therein may be formed by bonding the first substrate BS1 and the second substrate BS2 face-to-face. When using the structure, an additional manufacturing process for configuring the sealing body (package) is not required. Therefore, the manufacturing process of the element structure may be simplified.

The element structure shown in FIGS. 1A and 1B is a Z-axis sensor structure that detects the change in the capacitance value of the capacitor (variable capacitor) c1 by a force applied in a direction (Z-axis direction) perpendicular to each substrate BS1 and BS2. Further, at least one of an X-axis sensor structure detecting a force in an X-axis direction and a Y-axis sensor structure detecting a force in a Y-axis direction may be added to the Z-axis sensor structure. In this case, the sensor structure having multi-axial sensitivity is implemented.

Further, in the example of FIG. 1C, as the spacer member, a spacer member 400 (400-1 and 400-2) including a conductive material as a component is used. The spacer member 400 (400-1 and 400-2) may be disposed around an area in which the first substrate BS1 and the second substrate BS2 overlap each other when seen in plan view and may be disposed at a central portion (or, in an inside area rather than in a peripheral portion) of the area.

In addition, in the example of FIG. 1C, an insulating layer 130 is disposed on the active layer 120-3 of the first substrate BS1. Further, an insulating layer 230 is disposed on the active layer 220-3 of the second substrate BS2 and a conductor layer 240 is disposed on the insulating layer 230. Further, the first substrate BS1 and the second substrate BS2 are connected (adhered) with each other by an adhesive layer (for example, non-conductive adhesive film (NCF), or the like) 414. In FIG. 1C, the adhesive layer (for example, non-conductive adhesive film (NCF), or the like) 414 is painted black (this is similarly applied in the following drawings).

In detail, the spacer member 400 (400-1 and 400-2) shown in FIG. 1C includes a resin core part (resin core) 410 formed by patterning resin and a conductive layer 412 formed to cover at least a portion of the surface of the resin core part 410. In other words, the space member 400 (400-1 and 400-2) shown in FIG. 1C is a conductive spacer member configured to include the resin core and the conductor layer (for example, metal layer) disposed on the resin core.

As the resin forming the resin core part 410, for example, a thermosetting resin (for example, epoxy resin) such as resin may be used. The resin is hardened and has rigidity, which serves to stably support (support at the predetermined distance d1) the second substrate BS2 on the first substrate BS1. Further, the conductor layer 412 is formed to cover (to contact at least the resin core) at least a portion of the surface of the resin core part 410.

Further, the thickness of the conductor layer 412 is thin (further, when the first substrate BS1 is bonded to the second substrate BS2, there may be a case in which an apex portion of the resin core is almost exposed). Accordingly, the distance d1 between the first substrate BS1 and the second substrate BS2 may be accurately determined as the height of the resin core part 410.

Further, since the conductor layer 412 covering at least a portion of the resin core part 410 is disposed, the conductor on the first substrate BS1 side and the conductor on the second substrate BS2 side may be connected with each other via the conductor layer 412.

Further, when, for example, the conductive spacer having the resin core structure is interposed between the insulating layer 130 of the first substrate BS1 side and the insulating layer 230 of the second substrate BS2, it does not exhibit a function to electrically conduct with the conductor layer 412 covering at least a portion of the resin core. In this case, the conductive spacer having the resin core structure may substantially serve as the insulating spacer. That is, whether or not the conductive spacer having the resin core structure exhibits the function of the patterned conductor layer 412 is determined according to whether or not the electrical conduction between the first substrate BS1 and the second substrate BS2 is obtained by the conductor layer 412.

As described above, the conductive spacer member 400 (400-1 and 400-2) having the resin core structure shown in FIG. 1C has both a function as a holding member and a function as a conductive member. Therefore, the bending prevention of the second substrate BS2 as the lid substrate and the interconnection between the conductor (not shown in FIG. 1C) such as a wiring disposed, for example, around the first substrate BS1 as the support substrate and the conductor (reference numeral 240 of FIG. 1C) such as wiring disposed, for example, around the second substrate BS2 may be implemented together. According to the technology, for example, the construction of a signal path for taking out electrical signals from the second substrate BS2 is facilitated.

Further, both of the spacer member 300 shown in FIG. 1B and the spacer member 400 (400-1 and 400-2) shown in FIG. 1C may be used and only the spacer member 400 (400-1 and 400-2) may be used (in any case, the predetermined distance d1 between the first substrate BS1 and the second substrate BS2 may be secured).

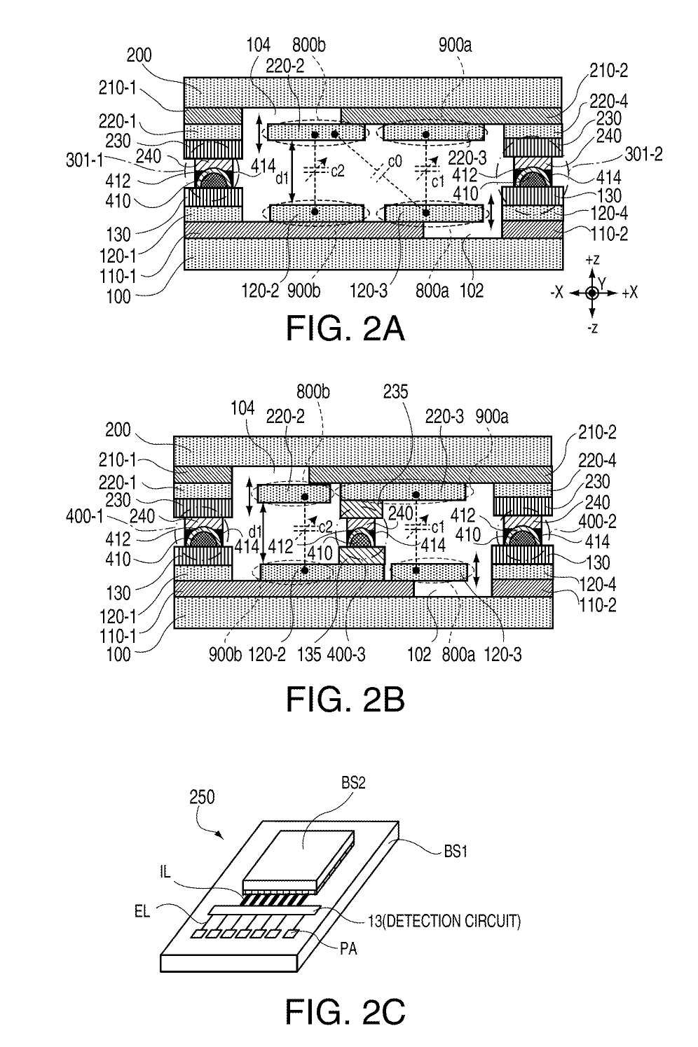

Next, the example of forming differential capacitors, the structure of the inertia sensor, and the like, will be described with reference to FIGS. 2A to 2C. FIGS. 2A to 2C show an example of an element structure including a first capacitor and a second capacitor and an example of an inertia sensor using the element structure. In FIGS. 2A to 2C, like parts common to FIGS. 1A to 1C are denoted by like reference numerals.

In the example of FIG. 2A, the first substrate BS is further provided with a second fixing part 900b that is fixed to the first insulating layer 110-1. Further, the second substrate BS2 is provided with a second movable beam 800b having the one end supported by the second insulating layer 210-2 and the other end having a second void part 104 provided therearound, wherein the second fixing part 900b and the second movable beam 800b are disposed to face each other, while being spaced by the predetermined distance d1. A second capacitor c2 is provided between the second fixing part 900b as the second fixing electrode and the second movable beam 800b as the second movable electrode. Accordingly, the element structure including two capacitors (first capacitor c1 and second capacitor c2) is implemented.

In the first capacitor c1, the first movable electrode is disposed on the first substrate BS1 side and the first fixing electrode is disposed on the second substrate BS2 side. Meanwhile, in the second capacitor c2, the second movable electrode is disposed on the second substrate BS2 side and the second fixing electrode is disposed on the first substrate BS1 side. That is, in the first capacitor c1 and the second capacitor c2, the positional relationship between the movable electrode and the fixing electrode is in a reverse state. Therefore, the first capacitor c1 and the second capacitor c2 may be used as differential capacitors.

When a force (acceleration or Coriolis force) is applied in a direction (Z-axis direction) perpendicular to each substrate BS1 and BS2, for example, in the first capacitor c1, the capacitance value of the first capacitor c1 is reduced by increasing the distance (gap between the capacitors) between the first movable electrode and the first fixing electrode (variation of the capacitance value of the first capacitor c1 is set to be −ΔC). In this case, in the second capacitor c2, the capacitance value of the second capacitor is increased by reducing the distance (gap between the capacitors) between the second movable electrode and the second fixing electrode (variation of the capacitance value of the second capacitor is set to be +ΔC).

Therefore, the differential detection signal is obtained by converting the variation in the capacitance values of each of the first capacitor c1 and the second capacitor c2 into the electrical signal. In-phase noise may be offset by differentiating the detection signal. Further, a direction of force (direction in which force is applied) may also be detected by detecting which one of two detection signals is increased. Further, since the capacitance value of the capacitor for detecting the inertia force is substantially increased and the movement of charge is increased by disposing the plurality of capacitors (at least the first capacitor c1 and second capacitor c2), the signal amplitude of the detection signal may be increased.

Further, when the structure of FIG. 2A is used, crosstalk (interaction) due to a coupling between the first capacitor c1 and the second capacitor c2 may be practically reduced to a level that does not cause any problem. For example, the case in which the fixing electrode of the capacitor is used as a common potential and the detection signal is obtained from the movable electrode is considered. Generally, as the element structure is miniaturized, the distance between the first capacitor c1 and the second capacitor c2 is shortened, the coupling due to parasitic capacitance (for convenience of description in FIG. 2A, parasitic capacitance c0 as shown in FIG. 2A) may easily occur between the movable capacitances of each capacitor.

However, according to the structure of the element structure shown in FIG. 2A, as described above, the first movable electrode 120-3 of the first capacitor c1 is disposed on the first substrate BS1 side, while the second movable electrode 220-2 of the second capacitor c2 is disposed on the second substrate BS2 side. Since each substrate BS1 and BS2 is spaced by the predetermined distance d1 (for example, Z-axis direction) in a direction perpendicular to the substrate, even though the first variable capacitor c1 and the second variable capacitor c2 are disposed to be adjacent to each other, the distance between the first movable electrode 120-3 and the second movable electrode 220-2 is secured, such that the crosstalk (interaction) due to the coupling between the first capacitor c1 and the second capacitor c2 is sufficiently reduced. Accordingly, the reduction in the detection sensitivity may be suppressed while miniaturizing the element structure.

In the example of FIG. 2B, the spacer member (400-1 to 400-3) having the resin core structure may be disposed around the area in which the first substrate BS1 and the second substrate BS2 overlap each other when seen in plan view and is also disposed at the central portion thereof. The spacer members 400-1 and 400-2 are spacer members that are disposed around the periphery. The spacer member 400-3 is a spacer member that is disposed at the central portion thereof.

The central portion of the second substrate BS2 as the lid substrate is a portion that is easily bent. Therefore, supporting the second substrate BS2 by the spacer member efficiently suppresses the bending of the second substrate. Further, as shown in FIG. 2B, for example, the second fixing part 900b on the first substrate BS1 side and the first fixing part 900a on the second substrate BS2 side may be electrically connected with each other by the conductive spacer member 400-3 having the resin core structure disposed at the central portion thereof. By this configuration, for example, it is easy to maintain the second fixing part 900b and the first fixing part 900a as the common potential (for example, ground potential).

FIG. 2C shows a perspective view of an example of the entire configuration of the inertia sensor. As shown in FIG. 2C, the second substrate BS2 as the lid substrate is fixed to the first substrate BS1 as the support substrate and the inertia sensor 250 including the sealing body (herein, the airtight sealing package) is formed. The surface of the first substrate BS1 is provided with a pad (external connection terminal) PA.

The variable capacitors c1 and c2, or the like and the detection circuit 13 that are disposed in the sealing body are connected with each other via a wiring IL. The detection circuit 13 and the pad PA are connected with each other by a wiring EL. Further, when the plurality of sensors are mounted in the sealing body, output signals from each sensor are drawn to the detection circuit 13 via the wiring IL. Further, in the example of FIG. 2C, the detection circuit 13 (including a signal processing circuit) is mounted on the first substrate BS1 (however, this is an example and there is no limitation to the example). The high-functional inertia sensor (MEMS inertia sensor) having a signal processing function may be implemented by mounting the detection circuit 13 on the first substrate BS1.

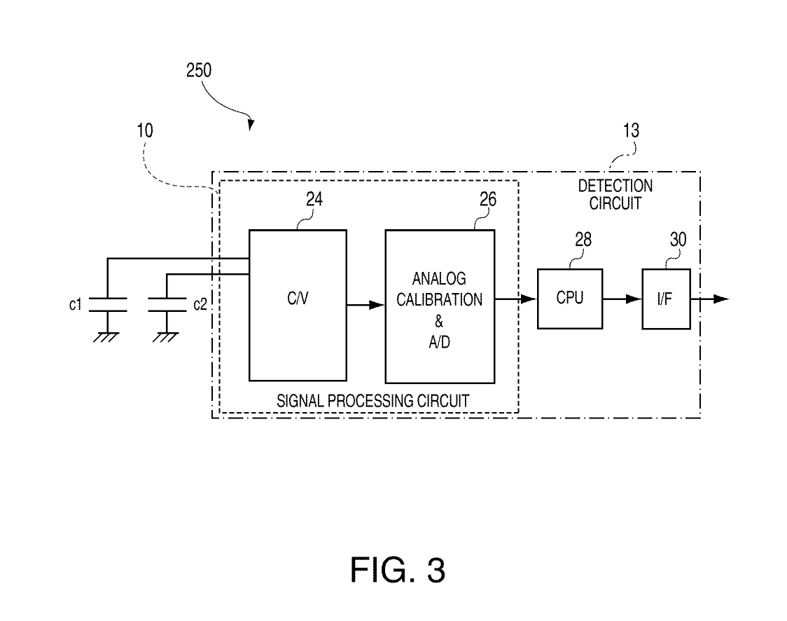

Next, a configuration example of the inertia sensor will be described with reference to FIG. 3. FIG. 3 is a diagram showing a configuration example of the inertia sensor. The inertia sensor 250 (for example, capacitive MEMS acceleration sensor) includes the first variable capacitor C1 and the second variable capacitor c2 and the detection circuit 13. As shown in FIG. 2C, the detection circuit 13 is disposed in, for example, an empty space on the first substrate BS1 and a signal processing circuit 10 is embedded therein.

As shown in FIG. 3, the detection circuit 13 includes the signal processing circuit 10, a CPU 28, and an interface circuit 30. The signal processing circuit 10 includes a C/V conversion circuit (capacitance value/voltage conversion circuit) 24, and an analog calibration and A/D conversion circuit 26. However, this example is only an example and the signal processing circuit 10 may also include the CPU 28 or the interface circuit (I/F) 30.

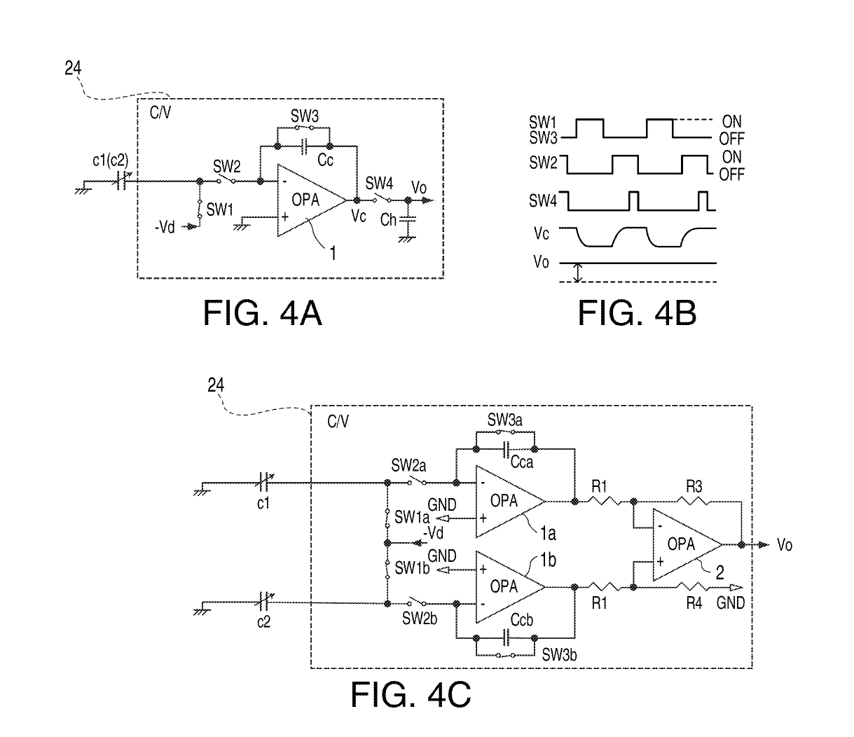

Next, an example of a configuration and an operation of the C/V conversion circuit (C/V conversion amplifier) will be described with reference to FIGS. 4A to 4C. FIGS. 4A to 4C show diagrams for illustrating a configuration and an operation of a C/V conversion circuit.

FIG. 4A shows a diagram of a basic configuration of the C/V conversion amplifier (a charge amplifier) using a switched capacitor and FIG. 4B shows a diagram of voltage waveforms of each part of the C/V conversion amplifier shown in FIG. 4A.

As shown in FIG. 4A, the basic C/V conversion circuit includes a first switch SW1 and a second switch SW2 (configuring a variable capacitor c1 (or c2) and a switched capacitor of an input unit), an operational amplifier (OPA) 1, a feedback capacitor (an integral capacitor) Cc, a third switch SW3 resetting the feedback capacitor Cc, a fourth switch SW4 sampling output voltage Vc from the operational amplifier (OPA) 1, and a holding capacitor Ch.

Further, as shown In FIG. 4B, the first switch SW1 and the third switch SW3 are controlled to be turned on/off at a first clock that is in-phase and the second switch SW2 is controlled to be turned on/off at a second clock that is a reverse phase from the first clock. The fourth switch SW4 is briefly turned on at an end of a period in which the second switch SW2 is turned on. When the first switch SW1 is turned on, both ends of the variable capacitor c1 (c2) are applied with a predetermined voltage Vd, such that charges are accumulated in the variable capacitor c1 (c2). In this case, since the third switch is in a turned on state, the feedback capacitor Cc is in a reset state (state in which both ends are short). Next, when the first switch SW1 and the third switch SW3 are turned off and the second switch SW2 is turned on, both ends of the variable capacitor c1 (c2) commonly become the ground potential, such that the charges accumulated in the variable capacitor c1 (c2) move towards an operational amplifier (OPA) 1.

In this case, since the charge amount is reserved, Vd·C1 (C2)=Vc·Cc is established, such that the output voltage Vc from the operational amplifier (OPA) 1 becomes (C1/Cc)·Vd. In other words, a gain of the charge amplifier is determined by a ratio of the capacitance value (C1 or C2) of the variable capacitor c1 (or c2) to the capacitance value of the feedback capacitor Cc. Next, when the fourth switch (sampling switch) SW4 is turned on, the output voltage Vc from the operational amplifier (OPA) 1 is maintained by the holding capacitor Ch. The held voltage is Vo and Vo is the output voltage from the charge amplifier.

As described above, the C/V conversion circuit 24 substantially receives the differential signal from each of two variable capacitors (first variable capacitor c1 and second variable capacitor c2). In this case, as the C/V conversion circuit 24, for example, as shown in FIG. 4C, the charge amplifier having a differential configuration may be used. The input end of the charge amplifier shown in FIG. 4C is provided with first switched capacitor amplifiers SW1a, SW2a, OPA1a, Cca, and SW3a amplifying a signal from the first variable capacitor c1 and second switched capacitor amplifiers SW1b, SW2b, OPA1b, Ccb, and SW3b amplifying a signal from the second variable capacitor c2. Further, the output signals (differential signals) from each of the operational amplifiers (OPAs) 1a and 1b are input to a differential amplifier (OPA) 2 and resistors R1 to R4 disposed at the output end thereof.

As a result, the amplified output signal Vo is output from the operational amplifier (OPA) 2. The base noise (in-phase noise) may be removed by using the differential amplifier. In addition, the configuration example of the above-mentioned C/V conversion circuit 24 is only an example and there is no limitation to the configuration.

### Second Embodiment

The second embodiment describes in detail the exemplary arrangement or shape of the electrode, or the like.

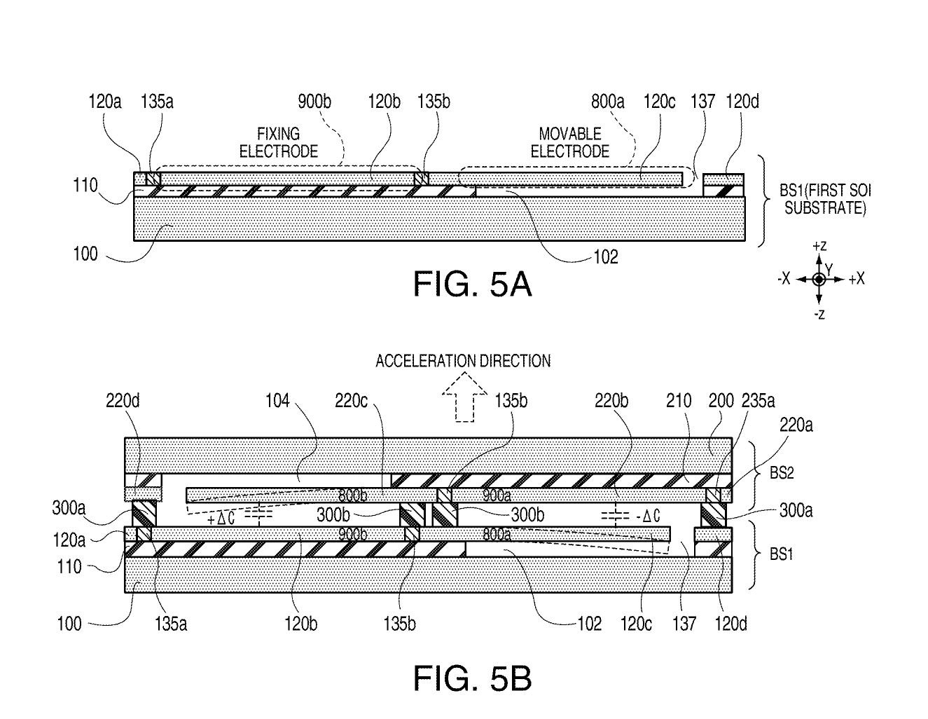

FIGS. 5A and 5B show a detailed example of the structure of the SOI substrate and a detailed example of the structure of the element structure using the SOI substrate. As shown in FIG. 5A, a first SOI substrate as the first substrate BS1 includes the first support layer 100, the first insulating layer 110, patterned first active layers 120a, 120b, and 120c, and insulating layers 135a and 135b buried into an opening part by the patterning of the first active layer. The insulating layers 135a and 135b are disposed in order to prevent a portion that does not require etching from being etched during a process of optionally removing the first insulating layer 110 by the etching.

As described above, the first movable beam 800a (including the first active layer 120c) configures the movable electrode of the first capacitor c1 and the second fixing part 900b (including the first active layer 120b) configures the fixing electrode of the second capacitor c2. The first cavity part 102 is formed around the first movable beam 800a.

As shown in FIG. 5B, the element structure (capacitor MEMS structure) including the first capacitor c1 and the second capacitor c2 is formed by bonding the first substrate (support substrate) BS1 and the second substrate (lid substrate) BS2 to face each other. The structure of the second substrate BS2 is similar to that of the first substrate BS1 and therefore, the description thereof will be omitted. The insulating spacer member 300 (300a and 300b) is interposed between the first substrate BS1 and the second substrate BS2.

When the element structure shown in FIG. 5B is applied with an upward acceleration in a direction perpendicular to both substrates, the first movable beam 800a and the second movable beam 800b are displaced downward in a direction perpendicular to both substrates by the inertia force. As a result, the variation of the capacitance value corresponding to −ΔC is generated in the first capacitor c1 and the variation of the capacitance value corresponding to +ΔC is generated in the second capacitor c2. Therefore, the differential signal (differential detection output) that is changed in response to the acceleration is obtained.

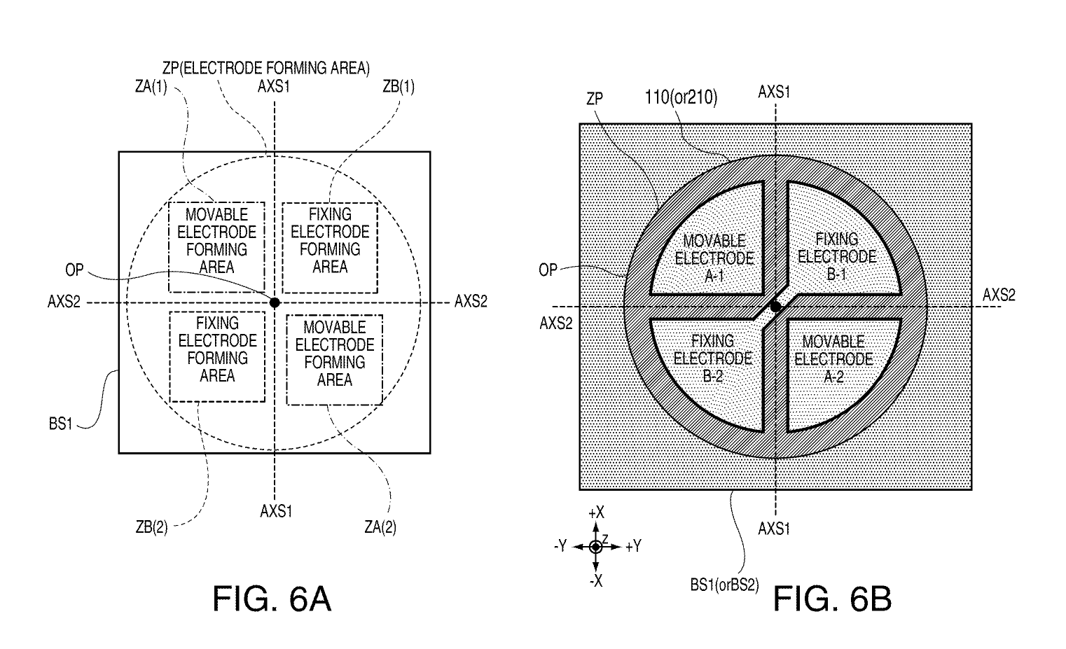

Next, the exemplary arrangement or shape of the electrode will be described with reference to FIGS. 6A and 6B. FIGS. 6A and 6B show an exemplary example of an electrode arrangement and an electrode shape in one SOI substrate configuring the element structure.

As shown in FIG. 6A, when seen in plan view, the forming area of the movable beam (movable electrode) in the SOI substrate is divided into two, that is, a pair of areas (that is, a first area ZA (1) and a second area ZA (2) that are formed in a pair). Similarly, when seen in plan view, the forming area of the fixing part (fixing electrode) in the SOI substrate is divided into two, that is, a pair of areas (that is, a first area ZB (1) and a second area ZB (2) that are formed in a pair).

The reason for dividing the electrode forming area into two is that the electrode forming area is disposed in point symmetry with respect to the center OP (center of chip) of the SOI substrate. That is, when seen in plan view, the first area ZA (1) and the second area ZA (2) that are the forming area of the movable beam (movable electrode) in the SOI substrate are disposed in point symmetry with respect to the center OP of the SOI substrate (center of chip) (that is, overlapping at the original position when each area is rotated 180°).

Similarly, when seen in plan view, the first area ZB (1) and the second area ZB (2) that are the forming areas of the fixing part (fixing electrode) in the SOI substrate are disposed in a point symmetry with respect to the center OP of the SOI substrate (center of chip) (that is, overlapping at the original position when each area is rotated 180°).

Further, when seen in plan view, the forming areas ZA (1) and ZA (2) of the movable beam (movable electrode) and when seen in plan view, the forming areas ZB (1) and ZB (2) of the fixing part (fixing electrode) are disposed in line symmetry with respect to a symmetrical axis AXS1, when seen in plan view, that passes through the center OP of the SOI substrate when seen in plan view (similarly applied even to symmetrical axis AXS2).

Further, although the above description uses a combination of the point symmetry and the line symmetry, only the point symmetry may be described. This case may be referred to as “a diagram showing the outer circumference of the electrode forming area ZP (shown by a dotted circle in FIG. 6A) including both of the forming areas ZA (1) and ZA (2) of the movable electrode and the forming areas ZB (1) and ZB (2) of the fixing electrode and which is a diagram of point symmetry with respect to the center OP of the substrate”.

As described above, in the embodiment of the invention, for the electrode forming area, the point symmetrical arrangement (when rotating 180° based on a symmetrical point, there is an arrangement so as to overlap an original diagram (diagram showing an original area)) is adopted and the line symmetrical arrangement (when folding based on the symmetrical axis, there is an arrangement so as to overlap an original diagram (diagram showing an original area)) is adopted. As a result, for example, the electrode arrangement layout of each of the first substrate BS1 and the second substrate BS2 may be made common. Therefore, the substrate is efficiently manufactured.

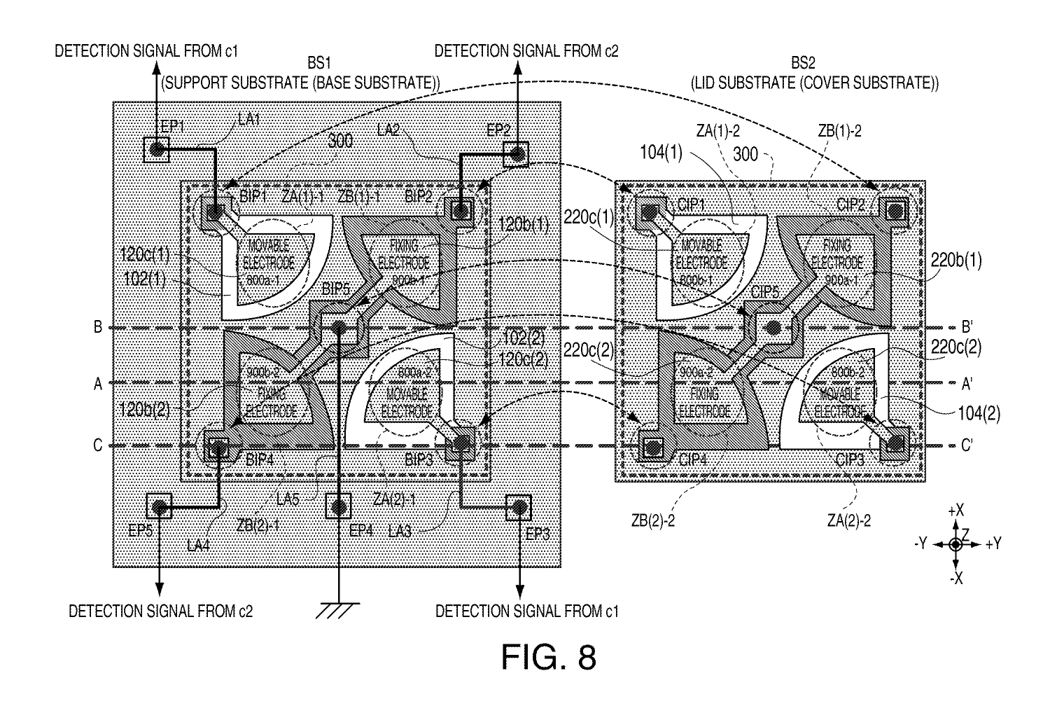

For example, after two sheets of SOI substrates adopting the common electrode arrangement layout are prepared and each SOI substrate is processed by using a common mask, each SOI substrate faces the other to be connected face-to-face. As a result, the forming area of the first movable beam (first movable electrode) on the first substrate and the forming area of the first fixing part (first fixing electrode) on the second substrate are in an opposing state, such that the first capacitor c1 is formed and similarly, the forming area of the second movable beam (second movable electrode) on the second substrate BS2 and the forming area of the second fixing part (second fixing electrode) on the first substrate are in an opposing state, such that the second capacitor c2 is formed (for example, see FIG. 8).

Hereinafter, an example of forming the first capacitor c1 will be described with reference to FIG. 8. In FIG. 8, the first movable beam (first movable electrode) disposed on the first substrate BS1 is divided into two, that is, 800a-1 and 800a-2. The forming area of the first movable beam (first movable electrode) 800a-1 becomes ZA (1)-1 and the forming area of the first movable beam. 800a-2 becomes ZA (2)-1. For example, the notation “ZA (1)-1” means that the “first electrode forming area among the fixing electrode forming area ZA that is divided into two and the electrode forming area disposed on the first substrate”. This is similarly applied also to other notations.

Further, in FIG. 8, a forming area of a first fixing part (first fixing electrode) 900a-1 on the second substrate BS2 becomes ZB (1)-2 and a forming area of the first fixing part 900a-2 becomes ZB (2)-2. When the first substrate BS1 and the second substrate BS2 are disposed to face each other, ZA (1)-1 and ZB (1)-2 face each other and ZA (2)-1 and ZB (2)-2 face each other, such that the first capacitor c1 is formed.

This is similarly applied also to the second capacitor c2. That is, when the first substrate BS1 and the second substrate BS2 are disposed to face each other, ZB (1)-1 and ZA (1)-2 face each other and ZB (2)-1 and ZA (2)-2 face each other, such that the second capacitor c2 is formed.

Herein, referring back to FIGS. 6A and 6B, the description will be continued. When the electrode arrangement as shown in FIG. 6A is not adopted, the electrode arrangement layout for the first substrate and the electrode arrangement layout for the second substrate need to be in a horizontally (or vertically) inverted layout, when seen in plan view (otherwise, when each substrate is bonded to the other face-to-face, the first capacitor c1 and the second capacitor c2 may not be formed), such that the electrode arrangement layout needs to be changed corresponding to each substrate, thereby degrading the manufacturing efficiency of the substrates.

FIG. 6B shows an example of the exemplary shape of the electrode. In the example of FIG. 6B, movable electrodes A-1 and A-2 and fixing electrodes B-1 and B-2 are disposed on the first insulating layer (in the case of the first substrate, reference numeral 110 and in the case of the second substrate, reference numeral 210).

Further, the shape of the movable electrodes A-1 and A-2 and the fixing electrodes B-1 and B-2, respectively, when seen in plan view, is patterned as a shape obtained by dividing a circle into four. The fixing electrodes B-1 and B-2 are commonly connected.

Substantially, the movable electrodes A-1 and A-2 are electrically commonly connected. For example, the movable electrodes A-1 and A-2 may be electrically connected to each other (connection example using a circuit) by commonly connecting each wiring (not shown) for taking out the signals from the movable electrodes A-1 and A-2.

In the example of FIG. 6B, the movable electrode (movable beam) has point symmetry with respect to the center OP of the SOI substrate when seen in plan view, also for the electrode shape, the fixing electrode (second fixing part) also has point symmetry with respect to the center OP of the SOI substrate when seen in plan view, also for the electrode shape, and the movable electrode (movable beam) and the fixing electrode (fixing part) have line symmetry with respect to the symmetrical axis AXS1 or AXS2, when seen in plan view, that passes through the center OP of the SOI substrate also for the electrode shape, when seen in plan view.

In the SOI substrate (that is, first substrate BS1 and second substrate BS2, respectively), even for the electrode arrangement and electrode shape, the capacitance values of the first capacitor c1 and the second capacitor c2 may be determined with higher accuracy by securing the point symmetry and the line symmetry.

As described above, the first capacitor c1 and the second capacitor c2 configure the differential capacitors, such that the change in the capacitance values C1 and C2 generated in each capacitor c1 and c2 is different in only a sign but is preferably the same in an absolute value. When the electrode arrangement and the electrode shape as shown in FIG. 6B are adopted, the areas of each of the first capacitor c1 and the second capacitor c2 may be accurately determined by the electrode shape itself, such that the high precision differential detection output may be obtained.

### Third Embodiment

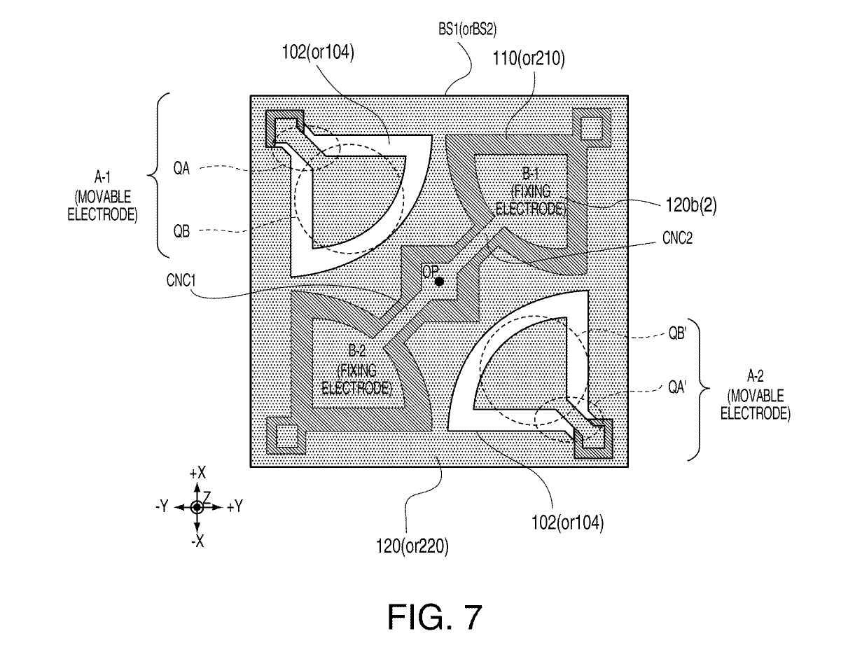

The third embodiment will describe an arrangement of a connection terminal, or the like, in the element structure. FIG. 7 shows an example of an arrangement of a connection terminal in the element structure. In the example of FIG. 7, similar to the example of FIG. 6B, as a shape of the movable electrodes A-1 and A-2 and the fixing electrodes B-1 and B-2, respectively, a shape obtained by dividing a circle into four when seen in plan view is adopted. However, when the element structure is actually manufactured, a connection terminal for configuring an electronic circuit is required. Therefore, the shape of the electrode part (the entire shape including a portion that does not function as the capacitive electrode) actually needs to be determined in consideration of the arrangement of the connection terminal.

In FIG. 7, the movable electrode A-1 includes a connection terminal BIP1, an elastic spring part QA, and a movable weight part (a dual capacitive electrode part) QB. The elastic spring part (an elastic deformation part) QA displaceably supports the movable weight part (a dual capacitive electrode part) QB on the void part (or cavity part) 102 (or 104). The movable weight part (dual capacitive electrode part) QB may be displaced in a direction (+Z-axis direction and −Z-axis direction) perpendicular to the substrate. Similarly, the movable electrode A-2 includes a connection terminal BIP3, an elastic spring part QA′, and a movable weight part (dual capacitive electrode part) QB′.

Further, since the connection terminal BIP2 and the connection terminal BIP3 may be electrically connected to other substrates that are disposed to face each other, they are connection terminals (a connection terminal to the other substrate) having an isolation pattern when seen in plan view. Further, a connection terminal BIP5 disposed at the center is a connection terminal for the fixing electrode that is used to maintain the fixing electrodes B-1 and B-2 in substrates disposed to face each other and the fixing electrodes B-1 and B-2 in other substrates that are disposed to face each other at a common potential.

FIG. 8 shows an example in which the first substrate is bonded to the second substrate. The left of FIG. 8 shows the first substrate (support substrate) BS1. The right of FIG. 8 shows the second substrate (lid substrate) BS2. In FIG. 8, a bidirectional arrow connecting the left diagram with the right diagram shows the mutually overlapping positional relationship when seen in plan view, when bonding between the chips.

In FIG. 8, the reason why the size of the first substrate (support substrate) BS1 is larger is that external connection terminals EP1 to EP5 are formed around the chips.

Further, in FIG. 8, a thick dotted line described around each chip shows the spacer member 300. The spacer member 300 has a closed linear shape when seen in plan view and when bonding between the chips, the spacer member also serves as the side wall (sealing member) that is a component of the sealing body.

Further, in the first substrate BS1 shown in the left of FIG. 8, as described above with reference to FIG. 5B, the movable electrode or the fixing electrode is formed by patterning the first active layer 120. FIG. 8 shows that for example, the movable electrode 120c (2) refers to the second movable electrode among the movable electrodes that are formed in the patterned first active layer 120c and are divided into two. The meaning of the reference numerals attached to other electrodes is also similar to the above description.

Further, in the left of FIG. 8, an area shown by an oblique line is an area in which the surface of the first insulating layer 110 is exposed and an area shown by white is the first void part (first cavity part) 102 (102 (1) and 102 (2)).

Further, in the left of FIG. 8, LA1 to LA5 are wirings connecting between the connection terminals. In addition, the conductive spacer member is actually connected to the connection terminal BIP5 of the center (the conductive spacer member is not shown in FIG. 8).

Further, in the left of FIG. 8, the detection signal (corresponding to half) of the first capacitor c1 is obtained from the external connection terminals EP1 and EP3. The detection signal (corresponding to half) of the second capacitor c2 is obtained from the external connection terminals EP2 and EP5. Further, for example, the external connection terminal EP4 connects to a ground. The ground potential is a common potential of the fixing electrode configuring the capacitor.

Further, in the second substrate BS2 shown in the right of FIG. 8, as described above with reference to FIG. 5B, the movable electrode or the fixing electrode is formed by patterning the second active layer 220. FIG. 8 shows that for example, a notation, a movable electrode 220c (2) indicates the second movable electrode among the movable electrodes that are formed in the patterned second active layer 220c and are divided into two. The meaning of the reference numerals attached to other electrodes is also similar to the above description. Further, in the right of FIG. 8, an area shown by an oblique line is an area in which the surface of the second insulating layer 210 is exposed and an area shown by white is the second void part (second cavity part) 104 (104 (1) and 104 (2)).

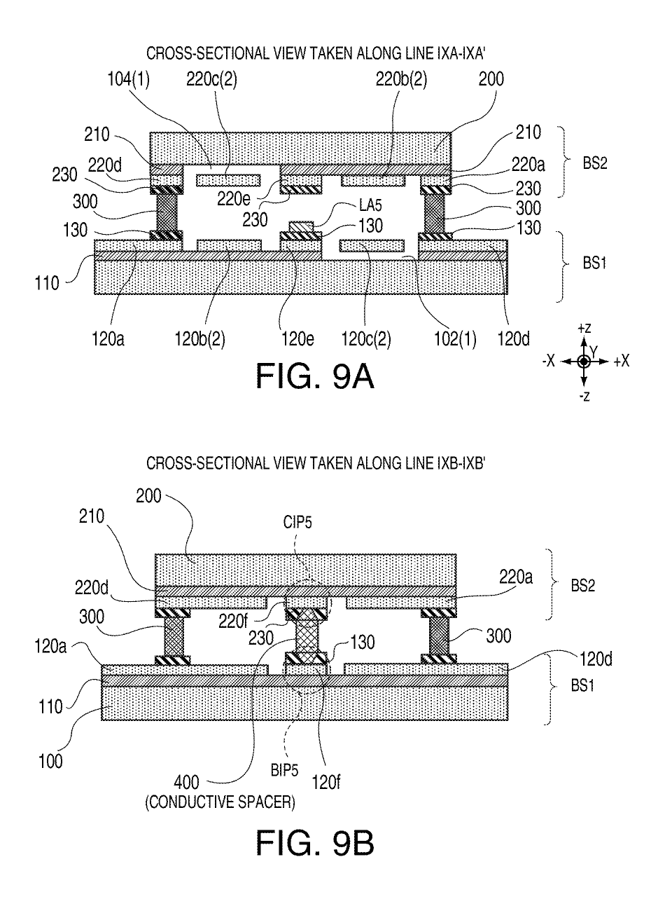

FIGS. 9A and 9B show cross-sectional views taken along line A-A′ and line B-B′ of the element structure after the chips are bonded as shown in FIG. 8. In FIGS. 9A and 9B, parts common in FIG. 8 are denoted by like reference numerals.

As shown in FIGS. 9A and 9B, the airtight sealing body having a closed space therein is formed by the first substrate BS1 and the second substrate BS2 and the spacer member 300.

Further, as shown in FIG. 9B, the conductive spacer member 400 is disposed between the connection terminal BIP5 of the first substrate BS1 side and the connection terminal CIP5 of the second substrate BS2 side. As shown in FIG. 8B, the connection terminal BIP5 of the first substrate BS1 side is connected to the external connection terminal EP4 by the wiring LA5. Therefore, the external connection terminal EP4, the wiring LA5, and the conductive spacer member 400 (in detail, the conductive spacer member 400 having the resin core structure described in FIG. 1C, or the like, may be used) are electrically connected. Each of the fixing electrode of the first substrate BS1 side and the fixing electrode of the second substrate BS2 side may be maintained at the common potential (GND, or the like) by using the path.

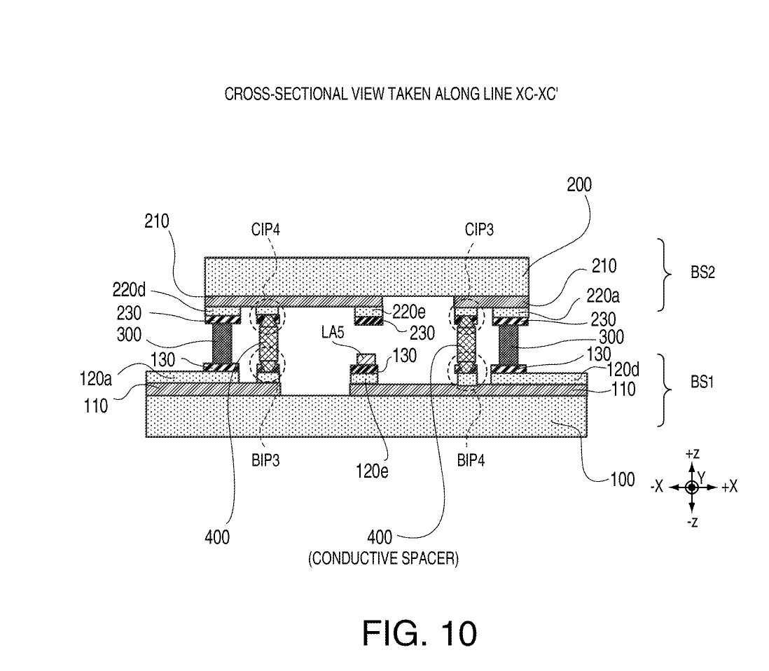

FIG. 10 shows a cross-sectional view taken along line C-C′ of the element structure after the chips are bonded as shown in FIG. 8. In FIG. 10, the conductive spacer member 400 is disposed between the connection terminal BIP3 of the first substrate BS1 side and the connection terminal CIP4 of the second substrate BS2 side and between the connection terminal BIP4 of the first substrate BS1 side and the connection terminal CIP3 of the second substrate BS2 side.

The connection between the connection terminal BIP3 and the connection terminal CIP4 is formal, which does not contribute to formation of the electronic circuit. Meanwhile, the detection signal may be taken out from the movable electrode (in the right of FIG. 8, corresponding to the patterned second active layer 220c (1)) in the second substrate BS2 by the connection between the connection terminal BIP4 and the connection terminal CIP3.

### Fourth Embodiment

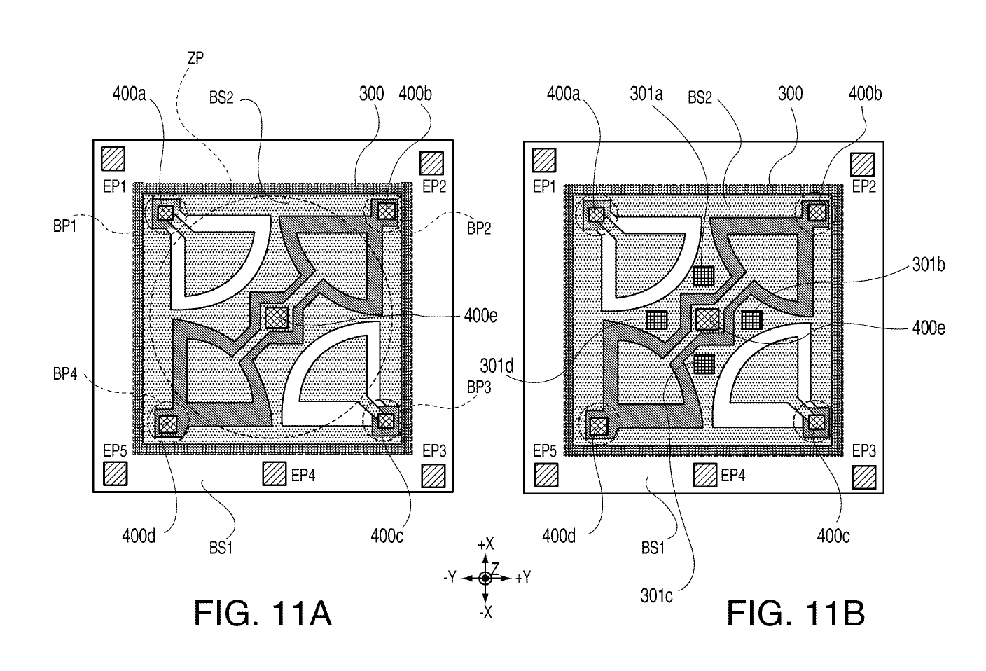

The fourth embodiment describes an example of the exemplary arrangement of the spacer member. FIGS. 11A and 11B show an example of an exemplary arrangement of the spacer member.

In FIG. 11A, the frame-shaped spacer member 300 having a closed linear shape when seen in plan view is disposed to enclose the capacitor forming area (in each substrate, the forming area of the fixing electrode and the movable electrode) in the peripheral portion (outer peripheral portion) of the area in which the first substrate BS1 and the second substrate BS2 overlap each other, when seen in plan view. In this case, the spacer member 300 becomes the first spacer member. As the spacer member 300, the insulating spacer configured of a resist layer or an insulating layer (including a multilayer such as an oxide layer or a resin layer, or the like), or the like, may be used. Further, the spacer member (conductive spacer member) including the conductive material having the resin core structure shown in FIG. 1C or FIGS. 2A and 2B may be used. The sealing body (airtight sealing body) having a space therein is formed due to the presence of the first spacer member 300.

That is, the first substrate BS1 may be used as a support substrate that supports the second substrate BS2, the second substrate BS2 may be used as the lid substrate configuring the lid part of the sealing body, and the first spacer member 300 may be used as the side wall for airtight sealing.

After the first spacer member 300 having a closed linear shape when seen in plan view is formed on at least one of the first substrate BS1 and the second substrate BS2, the element structure including the sealing body (package) is formed by bonding the first substrate BS1 and the second substrate BS2 face-to-face. In this case, the additional manufacturing process for configuring the sealing body (package) is not required, such that the manufacturing process of the element structure is simplified.

Further, in FIG. 11A, the spacer members 400a to 400d having a column shape are disposed around (an inside position rather than at a position at which the first spacer member 300 is formed) the area in which the isolation pattern is provided when seen in plan view and in which the first substrate BS1 and the second substrate BS2 overlap each other when seen in plan view. In the example of FIG. 11A, the spacers 400a to 400d having a column shape are disposed on each of the connection terminals BIP1 to BIP4 that are at four corners of the electrode forming areas (a portion in which the active layer 120 is disposed) of the first substrate BS1.

As a result, the first substrate BS1 and the second substrate BS2 may be connected via each of the plurality of connection terminals BIP1 to BIP4 that are disposed around the electrode forming area. In this case, the spacers 400a to 400d having a column shape become the second spacer member.

As described above, the plurality of second spacer members 400a and 400d may be disposed around the area in which the first substrate BS1 and the second substrate BS2 overlap each other when seen in plan view. For example, when the shape of the overlapping area with the first substrate BS1 and the second substrate BS2 is a quadrangular shape (substantially square in FIG. 11A) when seen in plan view, for example, each of the four second spacers 400a to 400d may be disposed at the four corners (near the four corners).

The arrangement position of the second spacer members 400a to 400d, or the like, and the number of second spacer members used may be appropriately adjusted in consideration of a mechanical balance. As a result, the bending of the second substrate BS2 that is the lid substrate may be efficiently prevented. Further, the first substrate BS1 and the second substrate BS2 may be electrically connected to each other.

The second spacer members 400a to 400d may be conductive spacer members including the conductive material as the component as shown in FIG. 1C or FIGS. 2A and 2B. The conductive spacer member has both of the function as the holding member and the function as the conductive member. Therefore, both of the prevention of the bending of the second substrate BS2 as the lid substrate and the interconnection between the conductor disposed around the first substrate BS1, or the like, and the conductor disposed around the second substrate may be implemented by using the conductive spacer member. According to the technology, for example, it is easy to build the signal path for taking out the electrical signals from the second substrate BS2.

Further, although the example of FIG. 11A uses both of the second spacer members 400a to 400d and the first spacer member 300, for example, only the second spacer members 400a to 400d may be used (in any case, the predetermined distance between the first substrate BS1 and the second substrate BS2 may be secured).

Further, in the example of FIG. 11B, a spacer member 400e is disposed at the central portion (near the center). The spacer member 400e has the isolation pattern when seen in plan view and is disposed at the central portion of the area in which the first substrate BS1 and the second substrate BS2 overlap each other when seen in plan view. Further, the spacer member 400e may be the conductive spacer member including the conductive material as the component as shown in FIG. 1C or FIGS. 2A and 2B. In this case, the spacer member 400e becomes the third spacer member.

The central portion of the second substrate BS2 as the lid substrate is a portion that is easily bent. Therefore, supporting the second substrate by the third spacer member efficiently suppresses the bending of the second substrate.

Further, the bending of the second substrate BS2 as the lid substrate may be efficiently suppressed and the conductor of the first substrate BS1 side and the conductor of the second substrate BS2 side may be electrically connected at the central portion thereof, by using the third spacer member as the conductive spacer member.

In the example of FIG. 11B, the group of the fixing electrodes of each substrate may be connected. For example, the case in which the second fixing electrode disposed on the first substrate BS1 and the first fixing electrode disposed on the second substrate BS2 becomes the common potential (ground potential, or the like) is considered. In this case, the second fixing electrode of the first substrate BS1 side and the first fixing electrode of the second substrate BS2 side are electrically connected to each other via the third spacer member 400e (conductive material portion that is a component) disposed at the central portion and each fixing electrode may equally and efficiently be set to the common potential by connecting the ground wiring (wiring LA5 of FIG. 8) to the common connection point between the second fixing electrode and the first fixing electrode. As described above, conductivity is imparted to the third spacer member disposed at the central portion, which serves to efficiently build the circuit.

Further, in the example of FIG. 11B, in addition to the spacer member shown in FIG. 11A, the spacer members 301a to 301d are disposed around the conductive spacer member 400e at the center. In this case, the spacer members 301a to 301d become the fourth spacer member. As the fourth spacer member, for example, the conductive spacer member including the conductive material as the component as shown in FIG. 1C or FIGS. 2A and 2B may be used.

As described above, the central portion of the second substrate BS2 as the lid substrate is a portion that is easily bent. In consideration of this aspect, in the example of FIG. 11B, the bending of the second substrate may be efficiently suppressed by densely disposing the plurality of spacers near the central portion.

### Fifth Embodiment

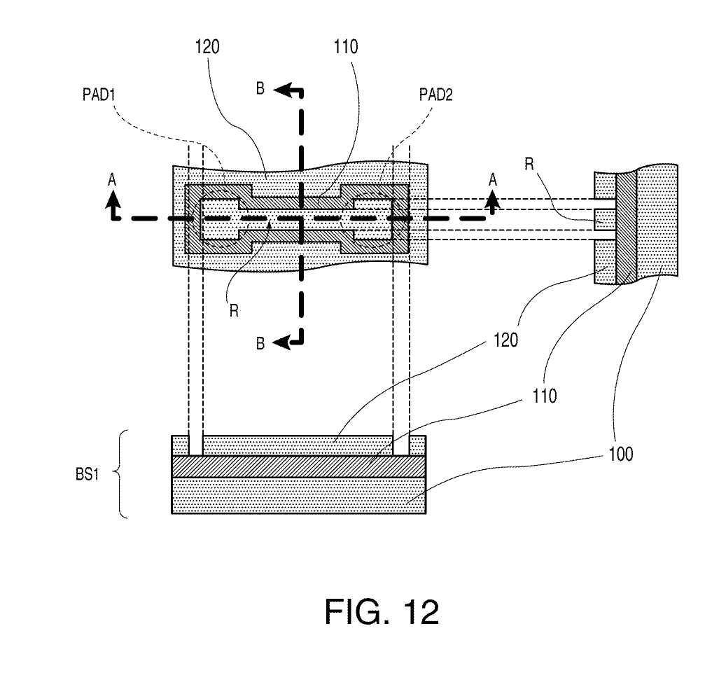

The fifth embodiment describes a structure example of the wiring necessary to configure the circuit. FIG. 12 shows an example of a structure of a wiring. A diagram shown in the upper left of FIG. 12 is a plan view, a diagram shown in the lower of FIG. 12 is a cross-sectional view taken along line A-A of the plan view, and a diagram shown in the right of FIG. 12 is a cross-sectional view taken along line B-B of the plan view. Further, FIG. 12 shows the structure example of the wiring in the first substrate BS1 (the structure of the wiring of FIG. 12 may also be used in the second substrate BS2).

In the example of FIG. 12, the active layer 120 of the first substrate BS1 is machined in a dogbone shape to form a wiring body R. The wiring body R has two terminals PAD1 and PAD2 disposed at both ends thereof.

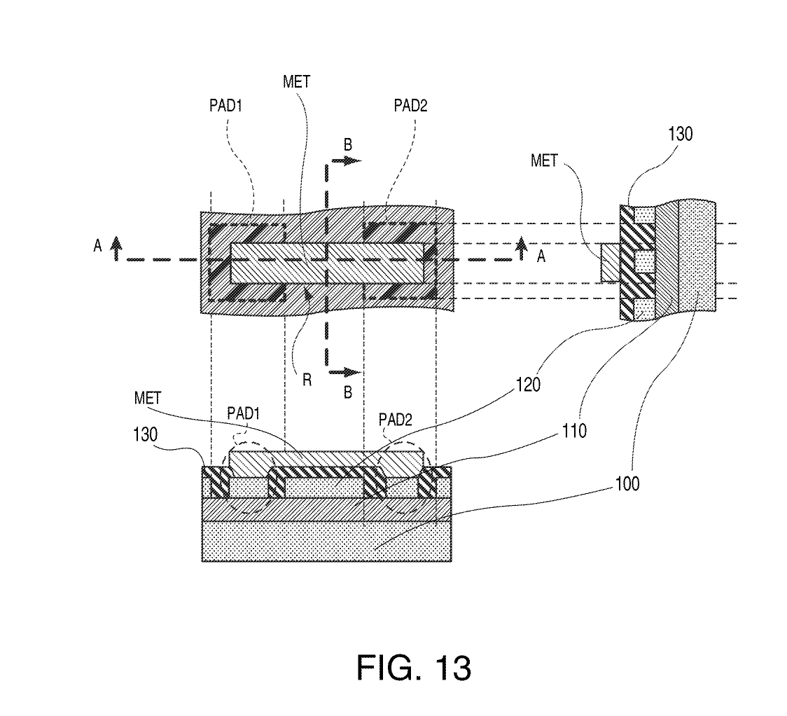

FIG. 13 shows another example of the structure of the wiring. A diagram shown in the upper left of FIG. 13 is a plan view, a diagram shown in the lower of FIG. 13 is a cross-sectional view taken along line A-A of the plan view, and a diagram shown in the right of FIG. 13 is a cross-sectional view taken along line B-B of the plan view. Further, FIG. 13 shows the structure example of the wiring in the first substrate BS1 (the structure of the wiring of FIG. 12 may also be used in the second substrate BS2).

In the example of FIG. 13, the insulating layer 130 is formed on the active layer 120 of the first substrate BS1. After the insulating layer 130 is patterned to form an opening part on a portion thereof, a conductor layer (herein, metal layer) MET is formed on the insulating layer 30. The wiring body R is formed by patterning the metal layer MET. Both ends of the metal layer MET are provided with two terminals PAD1 and PAD2. The metal layer MET is connected to the active layer 120 in the forming area of two terminals PAD1 and PAD2.

Further, the structure shown in FIG. 12 may also be used as the structure of the capacitor. That is, as the structure of the capacitor, a structure in which the insulating layer having the opening part and the conductor layer are further disposed on the movable beam and the fixing part configured by patterning the active layer and the conductor layer is connected to the movable beam or the fixing part via the opening part of the insulating layer may also be adopted.

### Sixth Embodiment

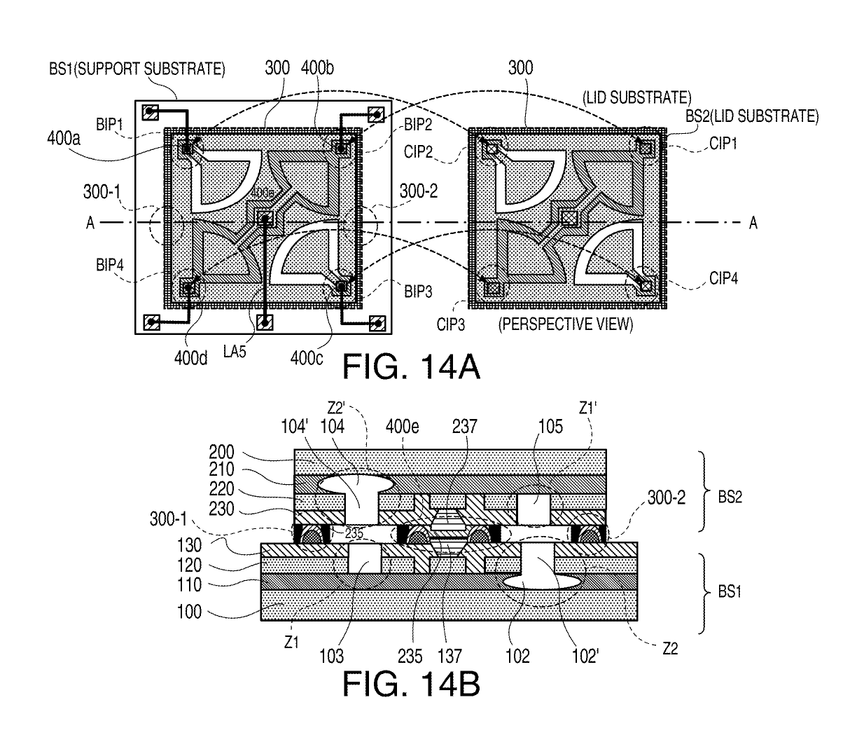

The sixth embodiment describes a detailed structure example of the element structure and a manufacturing method thereof. FIGS. 14A and 14B show a detailed structure example of the element structure. In FIGS. 14A and 14B, parts common in the drawings described above are denoted by like reference numerals.

FIG. 14A shows a layout of each of the two substrates bonded to each other and a correspondence relationship between respective substrates. The left of FIG. 14A shows the first substrate BS1 as the support substrate (support) and the right of FIG. 14A shows the second substrate BS2 as the lid substrate (lid body). The layout of the second substrate BS2 as the lid substrate (lid body) is a perspective view (which is to facilitate visual determination of the correspondence relationship between the first substrate and the second substrate, when bonding between the chips). Further, FIG. 14B shows a sectional structure taken along line A-A of the element structure shown in FIG. 14A.

As shown in FIG. 14A, in the first substrate BS1 (and second substrate BS2), the first spacer member 300, the second spacer members 400a to 400d, and the third spacer member 400e that are first described using FIGS. 11A and 11B are disposed. Further, the layout of each substrate shown in FIG. 14A is the same as one previously described using FIGS. 7 and 8. That is, for the electrode forming area and the electrode shape, the layout having point symmetry and line symmetry is adopted. Therefore, both substrates may be manufactured by using the common mask.

As shown in FIG. 14A, the element structure having the sectional structure shown in FIG. 14B is configured by bonding the first substrate BS1 and the second substrate BS2, while overlapping them.

In FIG. 14B, the first substrate BS1 includes the first support layer 100, the first insulating layer 110, the first active layer 120, the insulating layer 130 disposed on the first active layer, and a conductor 137 for central connection (a metal layer such as aluminum or tungsten, or the like) disposed on the central portion of the electrode forming area (or, the central portion of the chip).

Further, the second substrate BS2 includes the second support layer 200, the second insulating layer 210, the second active layer 220, the insulating layer 230 disposed on the second active layer, a conductor layer 235 (herein, metal layer) optionally formed on the insulating layer 230, and a conductor layer 237 (a metal layer such as aluminum or tungsten, or the like) for central connection disposed on the central portion.

Further, in the element structure shown in FIG. 14B, each of the first spacer member 300, the second spacer members 400a to 400d, and the third spacer member 400e has the resin core structure previously described using FIG. 1C or FIGS. 2A and 2B and the conductive spacer member including the conductive material (conductor layer 235) is used.

Further, in FIGS. 14A and 14B, the area Z1 shown being surrounded by a dotted line is the fixing electrode forming area of the first substrate BS1. In the fixing electrode forming area Z1 of the first substrate BS1, the cavity part 103 is formed as a result of optionally removing the active layer 120 and the insulating layer 130 by performing the patterning for forming the fixing electrode.

The area Z2 shown being surrounded by a dotted line is the movable electrode forming area of the first substrate BS1. In the movable electrode forming area Z2 of the first substrate BS1, the cavity part 102′ is formed as a result of optionally removing the active layer 120 and the insulating layer 130 by performing the patterning for forming the movable electrode. Further, as described above with reference to FIG. 7, for releasing the portion that serves as the elastic spring portion QA or the movable weight part QB in the movable electrode part from the first insulating layer 110, the first cavity part 102 is formed as a result of optionally removing the first insulating layer 110.

Further, the area Z1′ shown being surrounded by a dotted line is the fixing electrode forming area of the second substrate BS2. The cavity part 105 corresponds to the above-mentioned cavity part 103.

Further, the area Z2′ shown being surrounded by a dotted line is the movable electrode forming area of the second substrate BS2. The second cavity part 104 corresponds to the above-mentioned first cavity part 102. Further, the cavity part 104′ corresponds to the above-mentioned cavity part 102′.

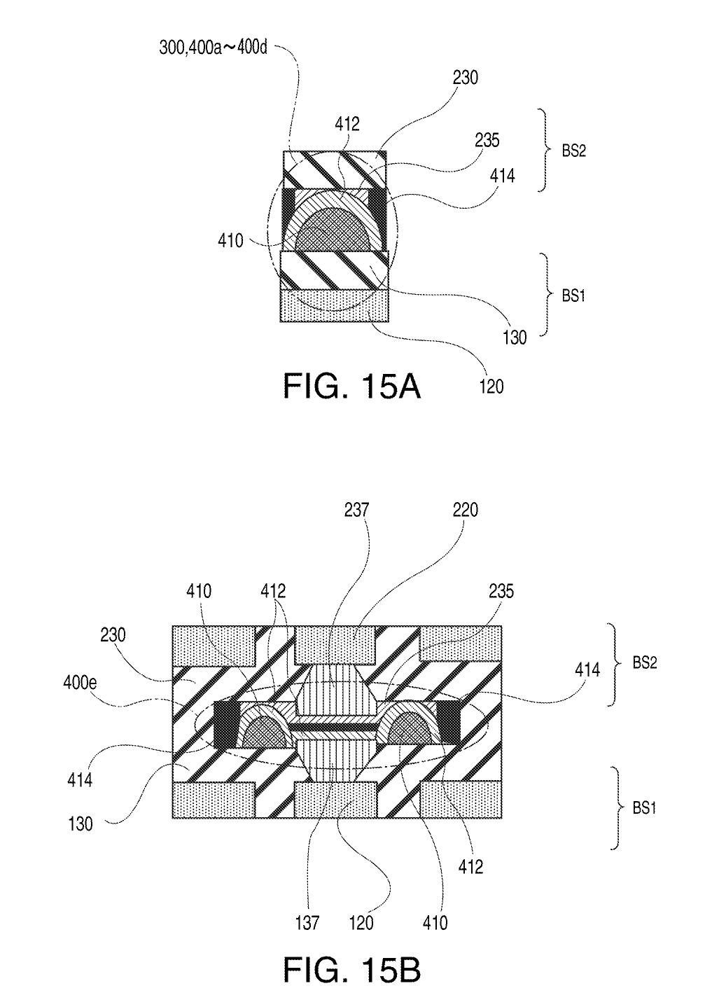

FIGS. 15A and 15B show enlarged views of a sectional structure around the spacer having a resin core structure in a state in which the first substrate is bonded to the second substrate. In this case, FIG. 15A shows the sectional structure regarding the first spacer member 300 (the spacer member disposed in the surroundings, for example, also used as the sealing member) or the second spacer members 400a to 400d (for example, the spacer member having the isolation pattern and disposed at the terminal positions of four corners).

The spacer having the resin core structure shown in FIG. 15A is disposed on the insulating layer 130 in the first substrate BS1. The spacer includes the resin core 410 and the conductor layer (conductor film) 412 made of, for example, aluminum, tungsten, or gold.

The conductive layer (conductive film) 412 is in contact with the conductor layer 235 disposed on the insulating layer 230 in the second substrate BS2, such that the electrical conduction between the conductive layer (conductive film) 412 and the conductor layer 235 is secured.

Further, the first substrate BS1 and the second substrate BS2 are connected (adhered) with each other by the adhesive layer 414 (for example, non-conductive adhesive film (NCF), or the like). In FIG. 15A, the adhesive layer (for example, non-conductive adhesive film (NCF), or the like) 414 is painted black.

FIG. 15B shows a sectional structure regarding the third spacer member 400e (the spacer member having the isolation pattern and disposed at the central portion of the electrode forming area). The active layer 120 of the first substrate BS1 contacts the conductor layer 137 (a metal layer such as aluminum or tungsten, or the like) for central connection of the first substrate BS1 side. The conductor layer 137 (a metal layer such as aluminum or tungsten, or the like) for central connection of the first substrate BS1 side contacts the conductive layer (conductive film) 412 formed to cover at least a portion of the resin core 410.

The adhesive film is deformed by compressing the first substrate BS1 and the second substrate BS2 face-to-face and the conductive layer (conductive film) 412 contacts the conductor layer 235 of the second substrate BS2 side. The conductor layer 235 contacts the conductor layer 237 (a metal layer such as aluminum or tungsten, or the like) for central connection of the second substrate BS2 side. The conductor layer 237 contacts the active layer 220 of the second substrate BS2. Therefore, the active layer 120 of the first substrate BS1 is electrically connected to the active layer 220 of the second substrate BS2.

Since the active layer 120 of the first substrate BS1 and the active layer 220 of the second substrate BS2 serve as the fixing electrode of the capacitor, the fixing electrodes of each substrate are connected to each other via the third spacer member 400e that is the conductive spacer member.

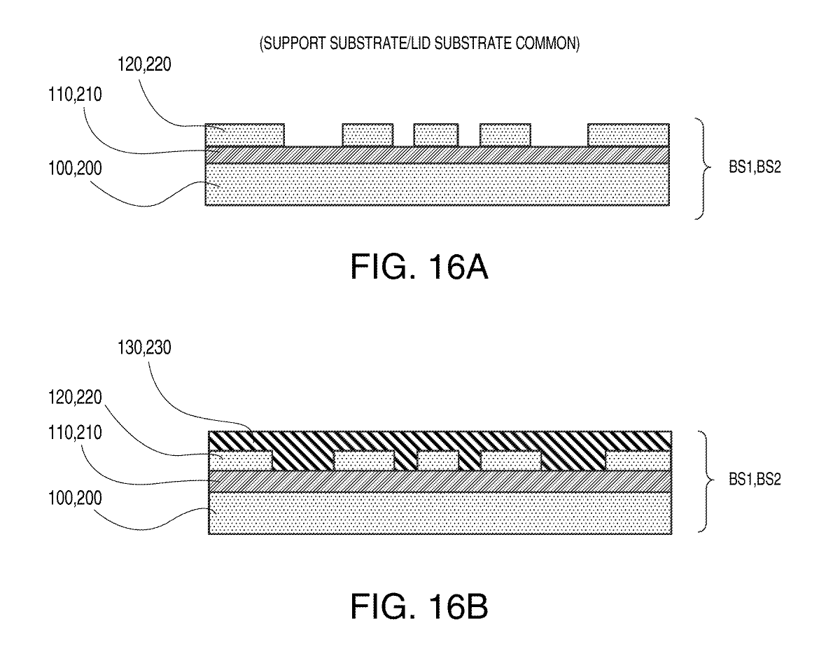

Next, an example of the manufacturing method of the element structure (element structure having the structure of FIG. 14B) will be described. Further, hereinafter, FIGS. 16A to 20B show cross-sectional views of line A-A of FIG. 14.

### First Process

FIGS. 16A and 16B show cross-sectional views of the element structure corresponding to a first process in a manufacturing method of an element structure (having the structure shown in FIG. 14B). For manufacturing the element structure, two sheets of the SOI substrates (the first SOI substrate and the second SOI substrate) are prepared. The first SOI substrate corresponds to the first substrate BS1 as the support substrate and the second SOI substrate corresponds to the second substrate BS2 as the lid substrate.

FIGS. 16A and 16B are processes common to each substrate. In FIG. 16A, the active layers 120 and 220 are patterned. In FIG. 16B, the insulating layers 130 and 230 are formed.

### Second Process

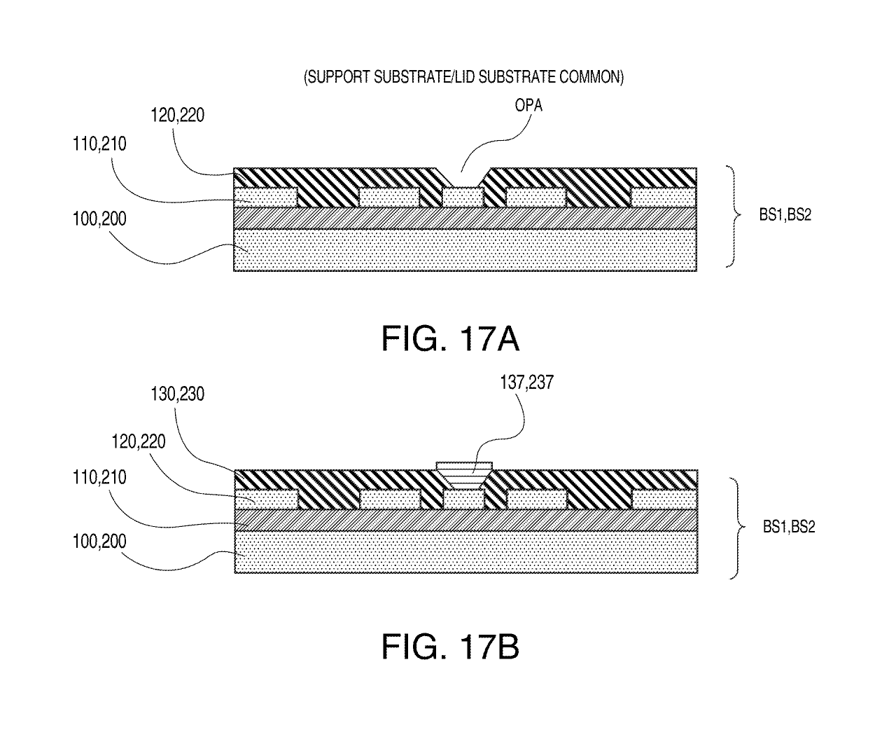

FIGS. 17A and 17B show cross-sectional views of the element structure in a second process. FIGS. 17A and 17B are processes common to each substrate. In FIG. 17A, the central portions of the insulating layers 130 and 230 is provided with an opening part OPA. In FIG. 17B, the conductor layers 137 and 237 for central connection are formed.

### Third Process

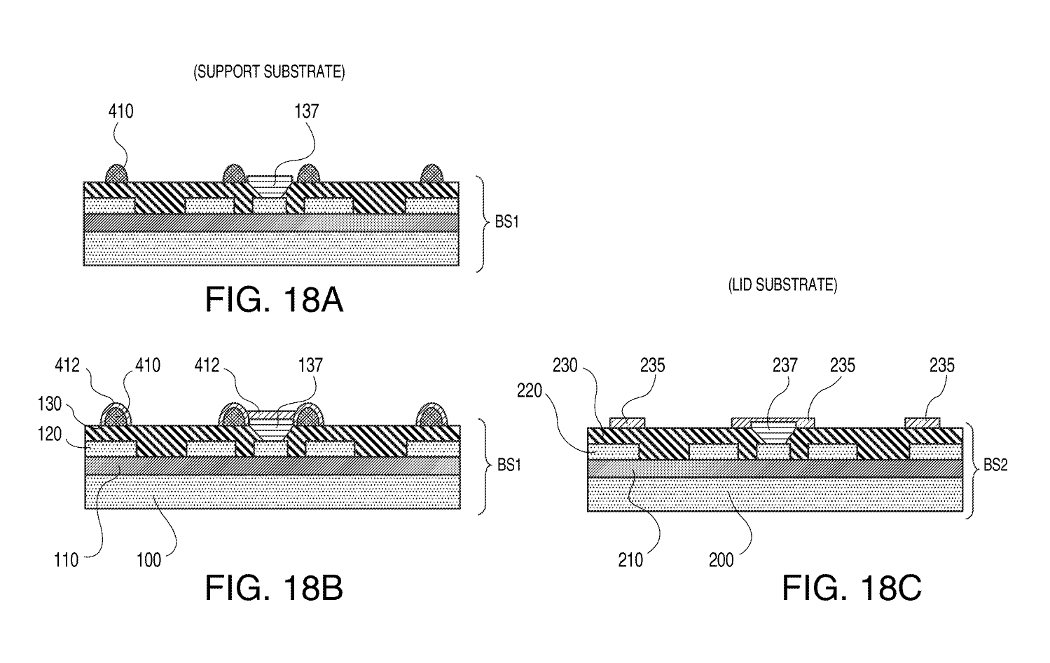

FIGS. 18A to 18C show cross-sectional views of the element structure in a third process. FIGS. 18A and 18B show cross-sectional views of the first substrate BS1 and FIG. 18C shows a cross-sectional view of the second substrate BS2.

In FIG. 18A, after patterning the resin layer formed on the substrate, the resin core part (resin core) 410 is formed by performing thermosetting. In FIG. 18B, after the conductive film 412 is formed on the entire surface, the conductive film is patterned. As a result, the patterned conductor layer 412 covering at least a portion of the resin core part 410 is formed.

Further, in FIG. 18C, in the second substrate BS2, the patterned conductor layer 235 is formed.

### Fourth Process

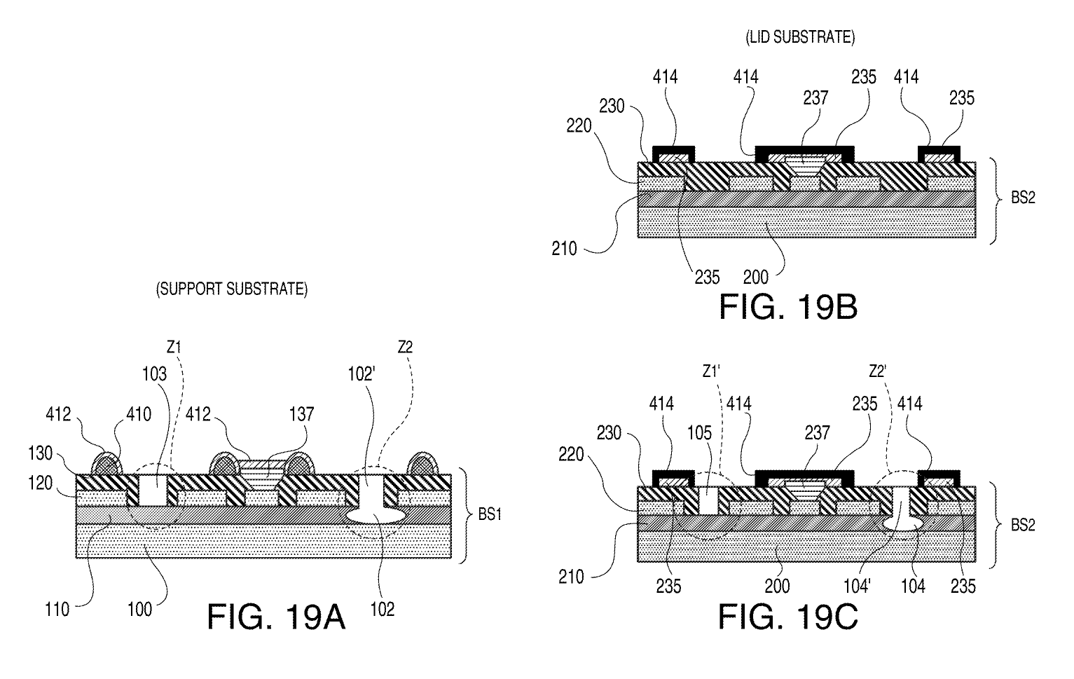

FIGS. 19A to 19C show cross-sectional views of the element structure in a fourth process. FIG. 19A shows a cross-sectional view of the first substrate BS1 and FIGS. 19B and 19C show cross-sectional views of the second substrate BS2.

In FIG. 19A, the fixing electrode forming area Z1 of the first substrate BS1 and the movable electrode forming area Z2 of the second substrate BS2 are formed.

Further, in FIG. 19B, after the adhesive film NCF is formed on the second substrate BS2, the adhesive film NCF is patterned. In FIG. 19C, the fixing electrode forming area Z1′ of the second substrate BS2 and the movable electrode forming area Z2′ of the second substrate BS2 are formed.

### Fifth Process

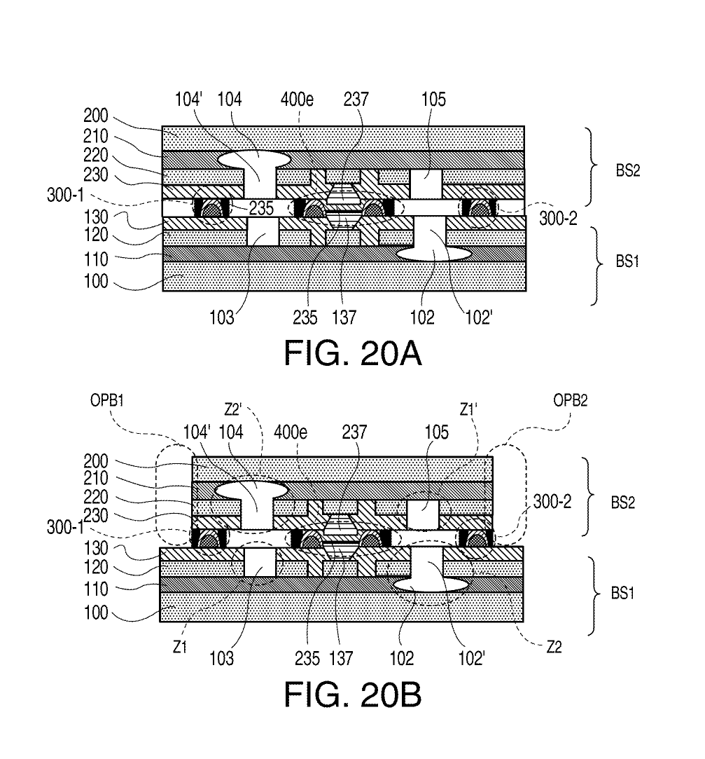

FIGS. 20A and 20B show cross-sectional views of the element structure in a fifth process. In FIG. 20A, the first substrate BS1 and the second substrate BS2 are bonded, while being opposed to each other. In FIG. 20B, the second substrate BS2 is diced, such that the outer peripheral portion thereof is removed by cutting. In the drawings, the removed portions OPA1 and OPA2 are shown being surrounded by a dotted line. As a result, the element structure shown in FIG. 14B is complete.

Since the element structure includes the sealing structure (package structure), the reliability is high. Further, for forming the sealing structure, the manufacturing process may be simplified without requiring an additional manufacturing process. Further, since the layout of two sheets of substrates that are bonded to each other is made to be common (including the same and similar ones), the manufacturing process is simplified even in this case.

### Seventh Embodiment

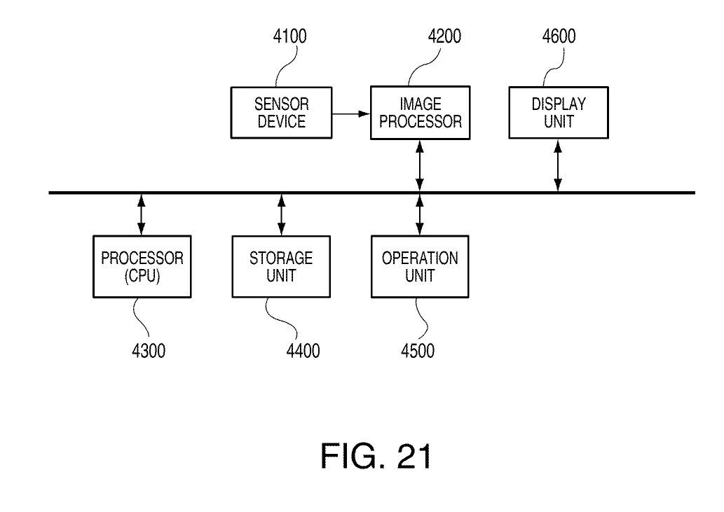

FIG. 21 shows an example of a configuration of an electronic device. The electronic device of FIG. 21 includes the inertia sensor (capacitive MEMS acceleration sensor, or the like) according to any one of the above embodiments. The electronic device is, for example, a game controller or a motion sensor, or the like.

As shown in FIG. 21, the electronic device includes a sensor device (capacitive MEMS acceleration sensor, or the like) 4100, an image processor 4200, a processor 4300, a storage unit 4400, a controller 4500, and a display unit 4600. Further, the configuration of the electronic device is not limited to the configuration of FIG. 21 and various modification embodiments in which a portion (for example, operation unit, display unit, or the like) of the component is omitted and other components are added, or the like, may be put into practice.

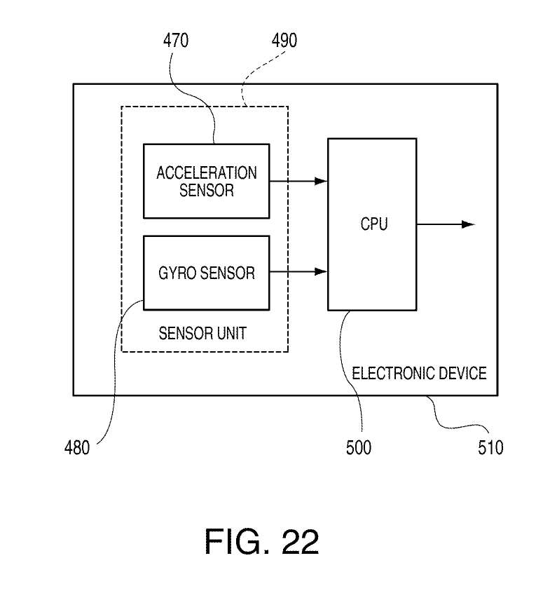

FIG. 22 shows another example of the configuration of the electronic device. An electronic device 510 shown in FIG. 22 includes a sensor unit 490 that includes an inertia sensor 470 (herein, a capacitive MEMS acceleration sensor) according to any one of the embodiments of the invention and a detection element 480 (herein, a capacitive MEMS gyro sensor detecting angular velocity) detecting the physical quantity different from the acceleration and a CPU 500 that performs predetermined signal processing based on the detection signal output from the sensor unit 490. In addition, the CPU 500 may also function as the detection circuit. The sensor unit 490 itself may be considered as one electronic device.

That is, the small-sized and high-performance electronic device may be implemented by using both of the small-sized and high-performance capacitive MEMS acceleration sensor 470 having excellent assembling performance and another sensor 480 (for example, a gyro sensor using the MEMS structure) detecting different kinds of physical quantities. That is, the sensor unit 470 as the electronic device, including a plurality of sensors or an upper electronic device 510 (for example, FA device, or the like) mounted with the sensor unit 470 may be implemented.

As described above, the small-sized and high-performance (high reliability) electronic device (for example, a game controller or a portable terminal, or the like) is implemented by using the element structure according to the embodiment of the invention. Further, a small-sized and high-performance (high reliability) sensor module (for example, motion sensor detecting a change in a person's posture, or the like: a kind of electronic device) may also be implemented.

As described above, at least one of the embodiments of the invention may facilitate, for example, the manufacturing of the element structure including the capacitor. Further, the small-sized and high-performance electronic device may be implemented.

As described above, although some embodiments have been described, the face that many modifications are possibly done may be easily understood by those skilled in the art that various modification can be made without substantially departing from the new matters and effects of the invention. Therefore, such modifications are all included in the scope of the invention.

For example, in the specification or the drawings, terms described together with different terms having a broader meaning or the same meaning may be substituted for other terms at least once in any place of the specification or the drawings. The invention may be applied to the inertia sensor. For example, the inertia sensor may be used as the capacitive acceleration sensor and the capacitive gyro sensor.

The entire disclosure of Japanese Patent Application No. 2010-121727, filed May 27, 2010 is expressly incorporated by reference herein.

What is claimed is:

1. An element structure comprising:
a first substrate that has a first support layer and a first movable beam having one end supported and the other end having a void part provided therearound; and
a second substrate that has a second support layer and a first fixing electrode formed side the first support layer,
wherein the second substrate is disposed to face above the first substrate,
the first movable beam is provided with a first movable electrode and the first fixing electrode and the first movable electrode are disposed to face each other, with a gap therebetween.

2. The element structure according to claim 1, wherein an insulating layer is provided at least one between the first support layer and the first movable beam and between the second support layer and the first fixing electrode.

3. The element structure according to claim 1, wherein the first substrate is further provided with a second fixing electrode,
the second substrate is further provided with a second movable beam having one end supported side the first support layer and the other end having a void part provided therearound,
the second movable beam is provided with a second movable electrode, and
the second fixing electrode and the second movable electrode are disposed to face each other, with a gap therebetween.

4. The element structure according to claim 3, wherein the first substrate is partitioned into first to fourth areas by a first axis passing through a center of the first substrate and a second axis orthogonal to the first axis at the center, when seen in plan view,
at least a portion of the first area and the second area disposed in a point symmetry with respect to the center is provided with a forming area of the first movable electrode,
at least a portion of the third area and the fourth area disposed in a point symmetry with respect to the center is provided with a forming area of the second fixing electrode,
the second substrate is partitioned into a fifth area facing the first area, a sixth area facing the second area, a seventh area facing the third area, and an eighth area facing the fourth area, when seen in plan view,
at least a portion of the fifth area and the sixth area is provided with a forming area of the first fixing electrode, and
at least a portion of the seventh area and the eighth area is provided with a forming area of the second movable electrode.

5. The element structure according to claim 4, wherein the first movable electrode is formed in the first area and the second area,
the first fixing electrode is formed in the fifth area and the sixth area,
the second movable electrode is formed in the seventh area and the eighth area, and
the second fixing electrode is formed in the third area and the fourth area.

6. The element structure according to claim 1, wherein a spacer member is disposed between the first substrate and the second substrate.

7. The element structure according to claim 6, wherein the spacer member is a frame shape, and
a sealing body is formed to have a space therein by the first substrate, the second substrate, and the space member.

8. The element structure according to claim 6, wherein the spacer member is a column shape and is disposed around the center of the area in which the first substrate and the second substrate overlap each other.

9. The element structure according to claim 6, wherein the spacer member includes a resin core part and a conductive layer formed to cover at least a portion of a surface of the resin core part.

10. An inertia sensor, comprising:
the element structure according to claim 1; and
a signal processing circuit that processes electrical signals output from the element structure.

11. An electronic device having the element structure according to claim 1.
